(19) United States
(12) Patent Application Publication
(10) Pub. No.: US 2010/0151131 A1
(43) Pub. Date: Jun. 17, 2010

(54) FILM DEPOSITION APPARATUS, FILM DEPOSITION METHOD, AND COMPUTER-READABLE STORAGE MEDIUM

(75) Inventors: KAZUTERU OBARA, Oshu-Shi (JP); Manabu Honma, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/629,106

(22) Filed: Dec. 2, 2009

(30) Foreign Application Priority Data
Dec. 12, 2008 (JP) 2008-317514

(51) Int. Cl. C23C 16/46; C23C 16/00

(52) U.S. Cl. 427/255.28; 118/725

(57) ABSTRACT

In a film deposition apparatus, a turntable is disposed in a vacuum container and includes a substrate placement area in which a substrate is placed. A substrate heating unit is disposed to heat the substrate placed on the turntable. First and second reactive gas supplying units are disposed at mutually distant locations in a rotational direction of the turntable to respectively supply first and second reactive gases to first and second processing areas adjacent to the substrate placement area. A separation gas supplying unit is disposed to supply a separation gas to a separation area located between the first and second processing areas in the rotational direction. An exhaust port is arranged to exhaust the first and second reactive gases and the separation gas from the turntable. A temperature control part is arranged to heat or cool the vacuum container.

### CROSS-REFERENCE TO RELATED APPLICATION

This application is based upon and claims the benefit of priority from Japanese patent application No. 2008-317514, filed on Dec. 12, 2008, the entire contents of which are incorporated by reference in their entirety.

### BACKGROUND OF THE INVENTION

1. Field of the Invention

This invention relates to a film deposition apparatus, a film deposition method, and a computer-readable storage medium for depositing a multiple-layered thin film on a surface of a substrate by sequentially supplying two or more mutually reactive gases to the substrate in a vacuum container and repeating the gas supplying cycle multiple times.

2. Description of the Related Art

As a film deposition technique in a semiconductor fabrication process, there has been known a so-called Atomic Layer Deposition (ALD) or Molecular Layer Deposition (MLD). In such a film deposition technique, a first reactive gas is adsorbed on a surface of a semiconductor wafer (referred to as a wafer hereinafter) under vacuum and then a second reactive gas is adsorbed on the surface of the wafer in order to form one or more atomic or molecular layers through reaction of the first and the second reactive gases on the surface of the wafer; and such an alternating absorbing of the gases is repeated plural times, thereby depositing a film on the wafer. This technique is advantageous in that the film thickness can be controlled at higher accuracy by the number of times alternately supplying the gases, and in that the deposited film can have excellent uniformity over the wafer. Therefore, this deposition method is thought to be promising as a film deposition technique that can address further miniaturization of semiconductor devices.

Such a film deposition method may be preferably used, for example, for depositing a dielectric material to be used as a gate insulator. When silicon dioxide (SiO₂) is deposited as the gate insulator, a bis (tertiary-butylamino) silane (BTBAS) gas or the like is used as a first reactive gas (source gas) and ozone gas or the like is used as a second gas (oxidation gas).

In order to carry out a film deposition method, use of a single-wafer deposition apparatus having a vacuum container and a shower head at a top center portion of the vacuum container has been under consideration. In such a deposition apparatus, the reactive gases are introduced into the chamber from the top center portion, and un-reacted gases and by-products are evacuated from a bottom portion of the chamber. When such a deposition chamber is used, it takes a long time for a purge gas to purge the reactive gases, resulting in an extremely long process time because the number of cycles may reach several hundred. Therefore, a deposition method and apparatus that enable high throughput is desired.

Under these circumferences, performance of ALD or MLD using a film deposition apparatus in which plural substrates or wafers are arranged on a turntable in a vacuum container along a rotational direction of the turntable has been considered. Specifically, in the film deposition apparatus of this type, two or more processing areas where each of the respective reactive gases is supplied respectively and the film deposition processing is performed are provided at different locations on the turntable in the vacuum container that are mutually distant in the rotational direction, and an intermediate area between the processing areas in the rotational direction is provided as a separation area in which a separation gas supplying unit is arranged for supplying a separation gas for separating the reactive gases of the processing areas.

When the film deposition processing is performed, the separation gas is supplied from the separation gas supplying unit, the separation gas spreads toward both sides of the turntable in the rotational direction, and the separation space for preventing mixing of the respective reactive gases in the separation area is formed. Each reactive gas supplied to the processing area is exhausted from the exhaust port of the vacuum container together with the separation gas. In this manner, while the reactive gas is supplied to the processing area and the separation gas is supplied to the separation area, the turntable is rotated and the wafer on the turntable is repeatedly moved from one of the processing areas 1 to another and vice versa, so that the ALD or MLD processing is performed. In such a film deposition apparatus, the reactive gas replacement in the processing areas is unnecessary and the thin films can be simultaneously formed on the two or more substrates. Thus, high throughput can be obtained.

For example, Patent Document 1 listed below discloses a film deposition apparatus in which two or more wafers are held in a vertical direction by a holding device and film deposition processing of ALD or MLD is performed in a reaction pipe made of quartz. This film deposition apparatus enables easy film deposition processing and easy manufacture of a large-sized apparatus. Manufacture of the film deposition apparatus made of metal, such as aluminum, has been considered.

In the above-mentioned film deposition processing, it is demanded that changing the heating temperature of a wafer be changed for every lot in a range of 350-600 degrees C. However, when heating the wafer by a heating unit in the film deposition apparatus of Patent Document 1, the vacuum container is also heated by the heat generated by the heating unit. If the vacuum container is made of aluminum, when the heating temperature of a wafer is changed to the lowest temperature (for example, about 350 degrees C.) in the above-mentioned range, the raised temperature of the vacuum container becomes too low. In such a case, when BTBAS gas is supplied to the wafer in the condition that the raised temperature of the vacuum container is too low, the BTBAS gas may liquefy on the surface of the vacuum container. Thus, it may be difficult to normally perform film deposition processing.

A conceivable method for preventing liquefaction of the BTBAS gas is that a heating mantle including a heat insulating material surrounding the vacuum container is arranged, and when film deposition processing is performed at low temperature, the vacuum container is heated further. However, when the heating temperature of a wafer is changed to the highest temperature (for example, about 600 degrees C.) in the above-mentioned range, the raised temperature of the vacuum container becomes too high, which makes it difficult to maintain the vacuum pressure in the vacuum container due to deterioration of the durability of the vacuum container or makes it difficult to support the wafer placement surface of the turntable horizontally. Thus, it may be difficult to normally perform film deposition processing. Moreover, when the heating mantle is provided as mentioned above, the heat dissipation from the vacuum container is suppressed by the heat insulating material and the raised temperature of the vacuum container becomes too high. The above problem may arise more easily.

As mentioned above, the heating temperature of the wafer affects the temperature of the vacuum container. When the vacuum container is heated, the temperature of the vacuum container affects the heating temperature of the wafer. Even if the temperature of the vacuum container is controlled to fall within the range in which liquefaction or solidification of the reactive gas does not take place and the durability of the vacuum container does not deteriorate, it is preferred to control the temperature of the vacuum container with good accuracy, in order to raise the quality of the film formed on the wafer. However, when the heating mantle is simply arranged, it is difficult to allow adequate heat dissipation from the vacuum container with the heat insulating material, and it is difficult to allow the temperature control of the vacuum container with high accuracy.

In the related art, film deposition apparatuses having a vacuum container and a rotation table on which plural wafers are arranged along the rotation direction have been proposed.

Patent Document 2 listed below discloses a deposition apparatus whose process chamber is shaped into a flattened cylinder. The process chamber is divided into two half circle areas. Each area has an evacuation port provided to surround the area at the top portion of the corresponding area. In addition, the process chamber has a gas inlet port that introduces separation gas between the two areas along a diameter of the process chamber. With these compositions, while different reactive gases are supplied into the corresponding areas and evacuated from above by the corresponding evacuation ports, a rotation table is rotated so that the wafers placed on the rotation table can alternately pass through the two areas. A separation area to which the separation gas is supplied has a lower ceiling than the areas to which the reactive gases are supplied.

However, because the reactive gases and the separation gas are supplied downward and then evacuated upward from the evacuation ports provided at the upper portion of the chamber, particles in the chamber may be blown upward by the upward flow of the gases and fall on the wafers, leading to contamination of the wafers.

Patent Document 3 listed below discloses a process chamber having a wafer support member (rotation table) that holds plural wafers and that is horizontally rotatable, first and second gas ejection nozzles that are located at equal angular intervals along the rotation direction of the wafer support member and oppose the wafer support member, and purge nozzles that are located between the first and the second gas ejection nozzles. The gas ejection nozzles extend in a radial direction of the wafer support member. A top surface of the wafers is higher than a top surface of the wafer supporting member, and the distance between the ejection nozzles and the wafers on the wafer support member is about 0.1 mm or more. A vacuum evacuation apparatus is connected to a portion between the outer edge of the wafer support member and the inner wall of the process chamber. According to a process chamber so configured, the purge gas nozzles discharge purge gases to create a gas curtain, thereby preventing the first reactive gas and the second reactive gas from being mixed.

However, the gas curtain cannot completely prevent mixture of the reactive gases but may allow one of the reactive gases to flow through the gas curtain to be mixed with the other reactive gas partly because the gases flow along the rotation direction due to the rotation of the wafer support member. In addition, the first (second) reactive gas discharged from the first (second) gas outlet nozzle may flow through the center portion of the wafer support member to meet the second (first) gas, because centrifugal force is not strongly applied to the gases in a vicinity of the center of the rotating wafer support member. Once the reactive gases are mixed in the chamber, an MLD (or ALD) mode film deposition cannot be carried out as expected.

Patent Document 4 listed below discloses a process chamber that is divided into plural process areas along the circumferential direction by plural partitions. Below the partitions, a circular rotatable susceptor on which plural wafers are placed is provided leaving a slight gap in relation to the partitions. In addition, at least one of the process areas serves as an evacuation chamber. In such a process chamber, process gas introduced into one of the process areas may diffuse into the adjacent process area through the gap below the partition, and be mixed with another process gas introduced into the adjacent process area. Moreover, the process gases may be mixed in the evacuation chamber, so that the wafer is exposed to the two process gases at the same time. Therefore, ALD (or MLD) mode deposition cannot be carried out in a proper manner by this process chamber.

Patent Document 5 listed below discloses a process chamber having four sector-shaped gas supplying plates each of which has a vertex angle of 45 degrees, the four gas supplying plates being located at angular intervals of 90 degrees, evacuation ports that evacuate the process chamber and are located between the adjacent two gas supplying plates, and a susceptor that holds plural wafers and is provided in order to oppose the gas supplying plate. The four gas supplying plates can discharge AsH₃ gas, H₂ gas, trimethyl gallium (TMG) gas, and H₂ gas, respectively.

However, Patent Document 5 does not provide any realistic measures to prevent two source gases (AsH₃, TMG) from being mixed. Because of the lack of such measures, the two source gases may be mixed around the center of the susceptor and through the H₂ gas supplying plates. Moreover, because the evacuation ports are located between the adjacent two gas supplying plates to evacuate the gases upward, particles are blown upward from the susceptor surface, which leads to wafer contamination.

Patent Document 6 listed below discloses a process chamber having a circular plate that is divided into four quarters by partition walls and has four susceptors respectively provided in the four quarters, four injector pipes connected into a cross shape, and two evacuation ports located near the corresponding susceptors. In this process chamber, four wafers are mounted in the corresponding four susceptors, and the four injector pipes rotate around the center of the cross shape above the circular plate while ejecting a source gas, a purge gas, a reactive gas, and another purge gas, respectively.

In the process chamber of Patent Document 6, after one of the injector pipes passes over one of the quarters, this quarter cannot be purged by the purge gas in a short period of time. In addition, the reactive gas in one of the quarters can easily flow into an adjacent quarter. Therefore, it is difficult to perform an MLD (or ALD) mode film deposition.

Patent Document 7 (Patent Documents 8, 9) listed below discloses a film deposition apparatus preferably used for an Atomic Layer CVD method that causes plural gases to be alternately adsorbed on a target (a wafer). In the apparatus, a susceptor that holds the wafer is rotated, while source gases and purge gases are supplied to the susceptor from above. Paragraphs 0023-0025 of Patent Document 7 describe partition walls that extend in a radial direction from a center of a chamber, and gas ejection holes that are formed in a bottom of the partition walls in order to supply the source gases or the purge gas to the susceptor, so that an inert gas as the purge gas ejected from the gas ejection holes produces a gas curtain. Regarding evacuation of the gases, paragraph 0058 of Patent Document 7 describes that the source gases are evacuated through an evacuation channel 30a, and the purge gases are evacuated through an evacuation channel 30b.

In the composition of Patent Document 7, the source gases can flow into a purge gas compartment from source gas compartments located in both sides of the purge gas compartment and be mixed with each other in the purge gas compartment. As a result, a reaction product is generated in the purge gas compartment, which may cause particles to fall onto the wafer.

Patent Document 1: Japanese Laid-Open Patent Publication No. 2008-186852

Patent Document 2: U.S. Pat. No. 7,153,542

Patent Document 3: Japanese Laid-Open Patent Publication No. 2001-254181

Patent Document 4: Japanese Patent No. 3,144,664

Patent Document 5: Japanese Laid-Open Patent Publication No. 04-287912

Patent Document 6: U.S. Pat. No. 6,634,314

Patent Document 7: Japanese Laid-Open Patent Publication No. 2007-247066

Patent Document 8: United States Patent Application Publication No. 2007/0218701

Patent Document 9: United States Patent Application Publication No. 2007/0218702

### SUMMARY OF THE INVENTION

In one aspect of the invention, the present disclosure provides a film deposition apparatus and a film deposition method which are able to prevent the heating temperature of a substrate from affecting film deposition processing, when depositing a multiple-layer laminated thin film on a surface of the substrate by sequentially supplying two or more mutually reactive gases to the substrate and repeating the gas supplying cycle multiple times.

In another aspect of the invention, the present disclosure provides a film deposition apparatus which deposits a multiple-layered thin film on a surface of a substrate by sequentially supplying two or more mutually reactive gases to the substrate in a vacuum container and repeating a gas supplying cycle, the film deposition apparatus including: a turntable disposed in the vacuum container and including a substrate placement area in which a substrate is placed; a substrate heating unit disposed to heat the substrate placed on the turntable; first and second reactive gas supplying units disposed over the turntable at mutually distant locations in a rotational direction of the turntable to respectively supply first and second reactive gases to first and second processing areas adjacent to the substrate placement area of the turntable; a separation gas supplying unit disposed over the turntable to supply a separation gas to a separation area located between the first and second processing areas in the rotational direction of the turntable, so that the first reactive gas in the first processing area and the second reactive gas in the second processing area are separated from each other by the separation gas; an exhaust port arranged to exhaust the first and second reactive gases and the separation gas from the turntable; and a temperature control part arranged to heat or cool the vacuum container.

In another aspect of the invention, the present disclosure provides a film deposition method which deposits a multiple-layered thin film on a surface of a substrate by sequentially supplying two or more mutually reactive gases to the substrate in a vacuum container of a film deposition apparatus and repeating a gas supplying cycle, the film deposition method including: placing a substrate in a substrate placement area of a turntable disposed in the vacuum container, and rotating the turntable; supplying first and second reactive gases to first and second processing areas adjacent to the substrate placement area of the turntable, respectively, by first and second reactive gas supplying units disposed over the turntable at mutually distant locations in a rotational direction of the turntable; supplying a separation gas to a separation area located between the first and second processing areas in the rotational direction of the turntable, by a separation gas supplying unit disposed over the turntable, so that the first reactive gas in the first processing area and the second reactive gas in the second processing area are separated from each other by the separation gas; exhausting the first and second reactive gases and the separation gas from the turntable through an exhaust port; heating the substrate placed on the turntable by a substrate heating unit of the film deposition apparatus; and heating or cooling the vacuum container by a temperature control part of the film deposition apparatus.

The aspects and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF THE DRAWINGS

FIG. 1 is a cross-sectional view illustrating the composition of a film deposition apparatus of an embodiment of the invention.

FIG. 2 is a perspective view illustrating the internal structure of the film deposition apparatus of the present embodiment.

FIG. 3 is a plan view of the film deposition apparatus of the present embodiment.

FIG. 4A and FIG. 4B are diagrams illustrating processing areas and separation areas in the film deposition apparatus of the present embodiment.

FIG. 5 is a cross-sectional view illustrating a portion of the film deposition apparatus of the present embodiment.

FIG. 6 is a perspective view of the film deposition apparatus of the present embodiment.

FIG. 7 is a diagram illustrating the way a separation gas (or a purge gas) flows.

FIG. 8 is a perspective view of the film deposition apparatus of the present embodiment.

FIG. 9 is a plan view illustrating a bottom surface of a vacuum container of the film deposition apparatus of the present embodiment.

FIG. 10 is a plan view illustrating a top surface of the vacuum container of the film deposition apparatus of the present embodiment.

FIG. 11 is a diagram for explaining the way a first reactive gas and a second reactive gas are separated by a separation gas and exhausted.

FIG. 12 is a plan view illustrating the composition of a base part in a modification of the film deposition apparatus of the present embodiment.

FIG. 13A and FIG. 13B are diagrams for explaining the dimensions of a projecting portion used in a separation area.

FIG. 14 is a plan view illustrating the composition of a film deposition apparatus of another embodiment of the invention.

FIG. 15 is a plan view illustrating the composition of a film deposition apparatus of another embodiment of the invention.

FIG. 16 is a perspective view illustrating the internal structure of a film deposition apparatus of another embodiment of the invention.

FIG. 17 is a plan view illustrating the composition of a film deposition apparatus of another embodiment of the invention.

FIG. 18 is a cross-sectional view illustrating the composition of a film deposition apparatus of another embodiment of the invention.

FIG. 19 is a plan view illustrating the composition of a substrate processing apparatus which uses the film deposition apparatus according to the invention.

### DETAILED DESCRIPTION OF PREFERRED EMBODIMENTS

A description will be given of embodiments of the invention with reference to the accompanying drawings.

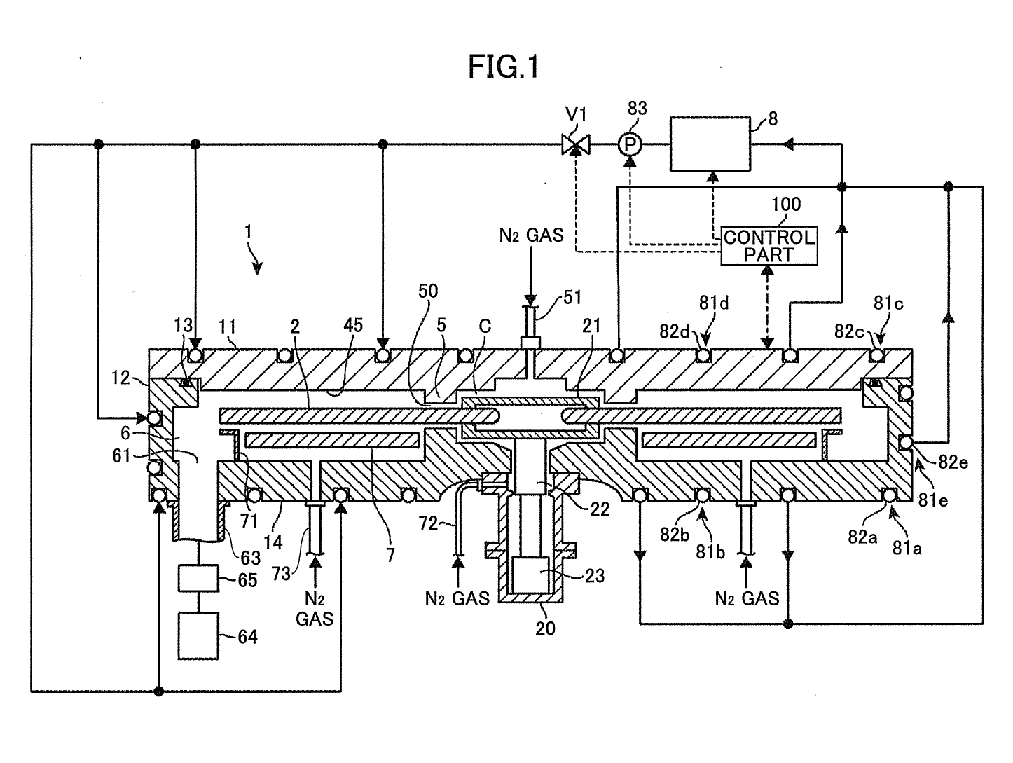

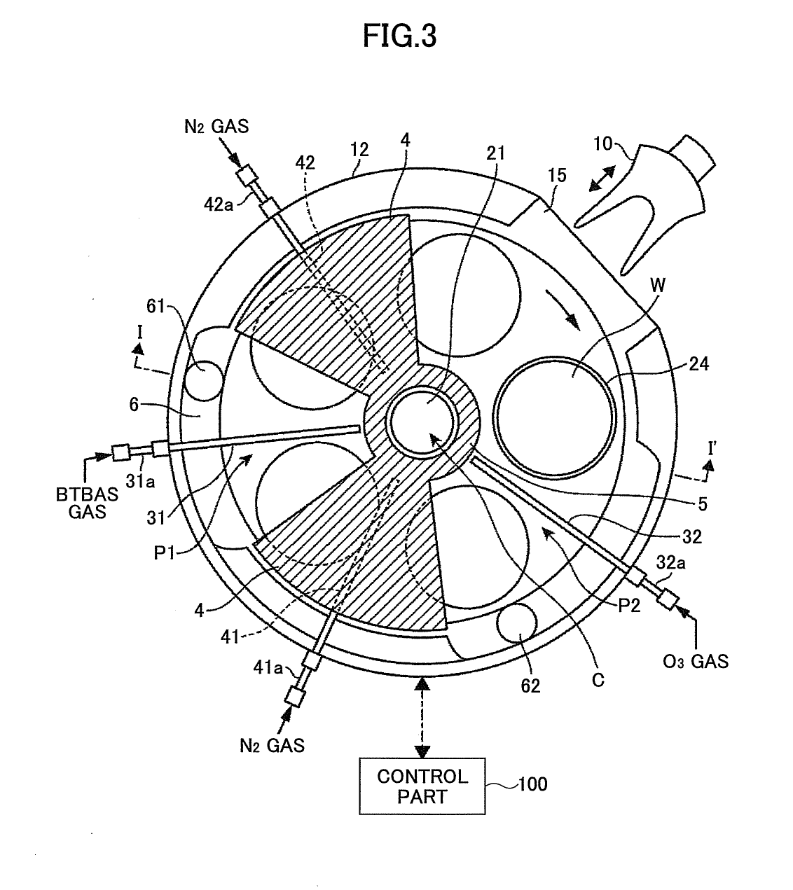

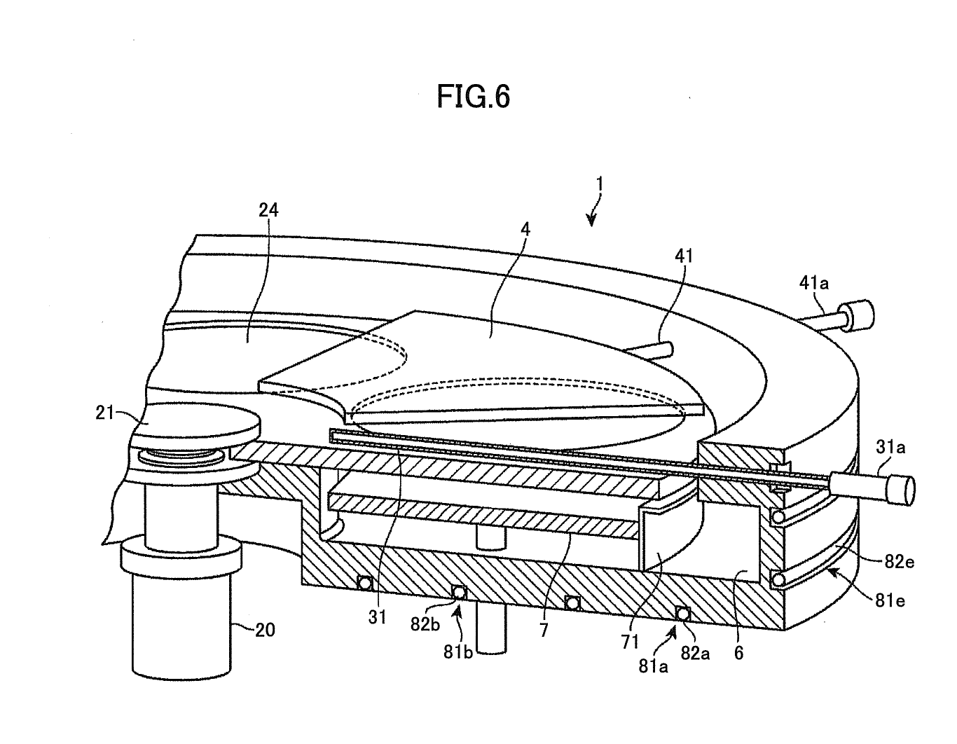

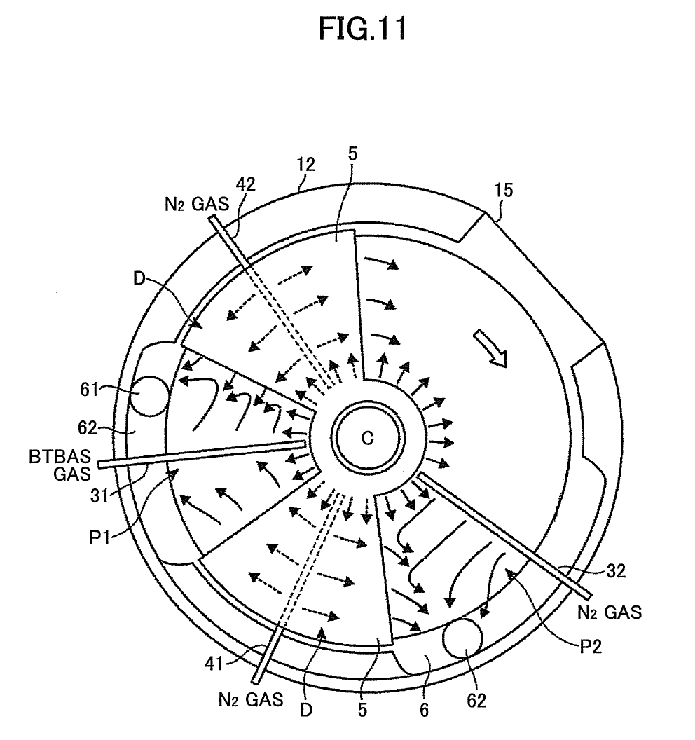

Referring to FIGS. 1 through 11, the composition of a film deposition apparatus of an embodiment of the invention will be described. The cross section of the film deposition apparatus of this embodiment illustrated in FIG. 1 is taken along line I-I′ indicated in FIG. 3.

As illustrated in FIGS. 1 through 3, the film deposition apparatus of this embodiment generally includes a vacuum container 1, a turntable 2, first and second reactive gas supplying portions 31, 32, and first and second separation gas supplying portions 41, 42. The vacuum container 1 is made of aluminum and it is a flattened container component having a generally circular configuration. The vacuum container 1 generally includes a top plate 11, a container main part 12, an O ring 13, and a base part 14.

The top plate 11 is arranged so that the top plate 11 may be separated from the container main part 12. The top plate 11 is pushed against the container main part 12 via the O ring 13 (which is a sealing member) by a reduced internal pressure of the vacuum container, so that an airtight condition is maintained. When the top plate 11 is separated from the container main part 12, the top plate 11 is lifted by a drive mechanism (which is not illustrated).

The turntable 2 is rotatably arranged so that the turntable 2 has a center of rotation at the center of the vacuum container 1. The turntable 2 generally includes case bodies 20 and 20a, a core part 21, a rotary shaft 22, a drive part 23, and recesses 24.

The turntable 2 is fixed at its center to the core part 21 of a cylindrical shape, and the core part 21 is fixed to the upper end of the rotary shaft 22 which extends in the perpendicular direction. The rotary shaft 22 penetrates a base part 14 of the vacuum container 1, and is attached at its bottom to the drive part 23. In this example, the drive part 23 rotates the rotary shaft 22 clockwise around the vertical axis. The rotary shaft 22 and the drive part 23 are accommodated in the cylindrical case body 20, and the upper surface of the case body 20 is open. The case bodies 20 and 20a attached together are arranged so that the flange part provided in the upper surface of the case body 20a is attached to the undersurface of the base part 14 of the vacuum container 1 in an airtight manner and the airtight condition of the internal atmosphere of the case bodies 20 and 20a to the external atmosphere is maintained.

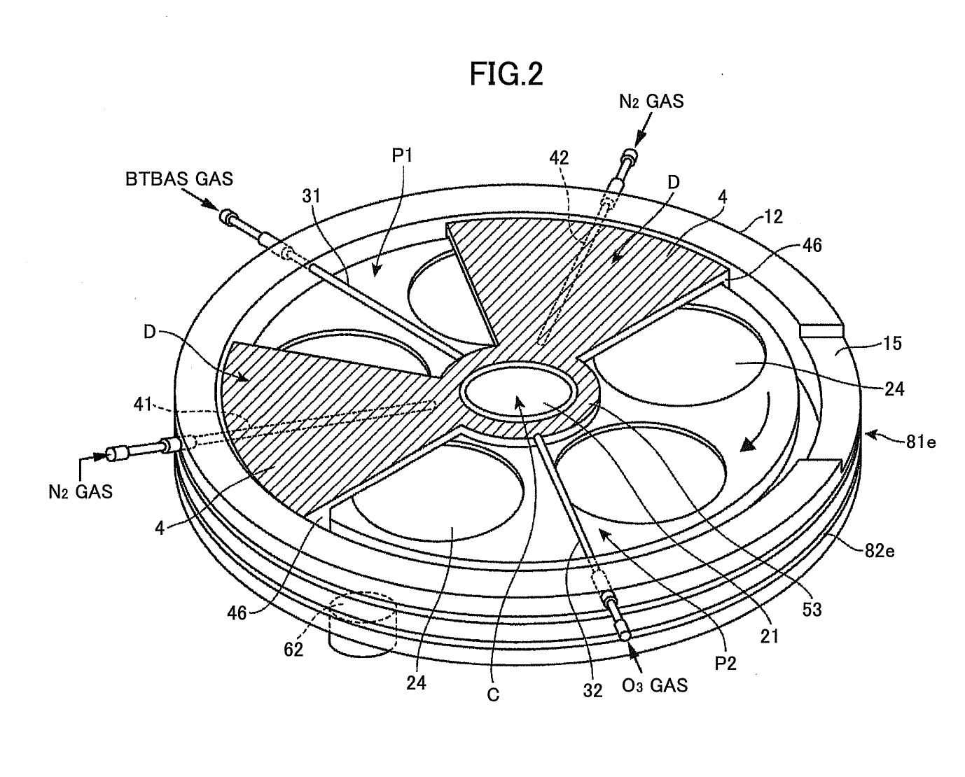

As illustrated in FIGS. 2 and 3, plural recesses 24 (five recesses in the illustrated example) are formed in the surface part of the turntable 2, in order to place five or more wafers W (which are substrates) on the turntable 2 in the rotational direction (the circumferential direction) of the turntable 2.

The recesses 24 have a circular configuration and each recess 24 has a diameter that is slightly larger than the diameter of the wafer W. Each recess 24 is for positioning the wafer W and preventing the wafer W from being thrown out by a centrifugal force when the turntable 2 is rotated. For the sake of convenience, only one wafer W placed in one recess 24 is illustrated in FIG. 3.

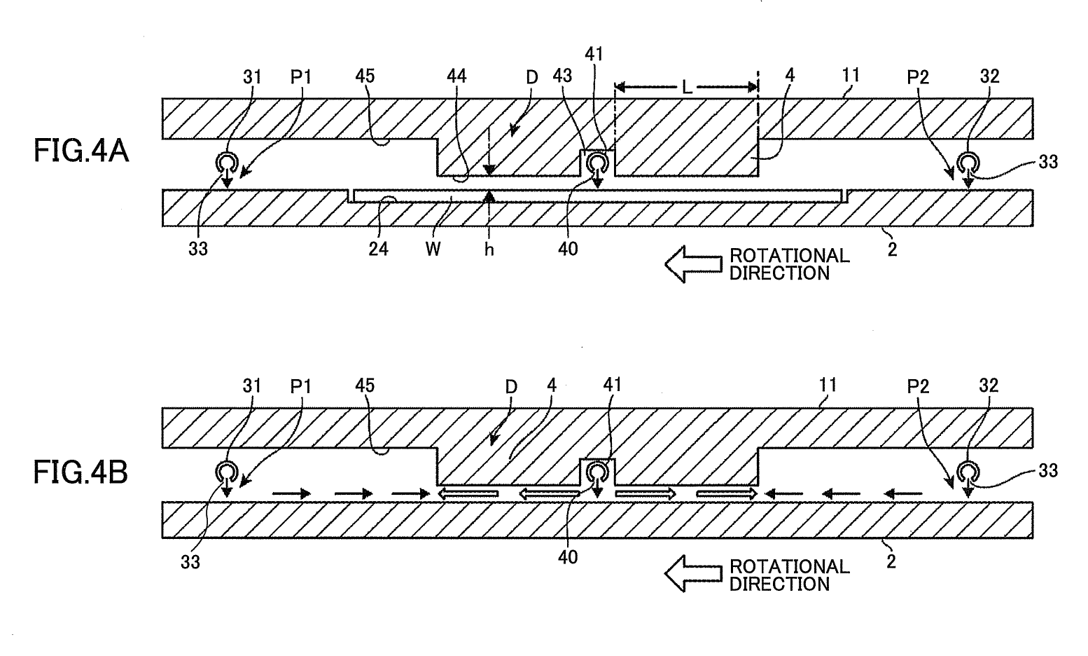

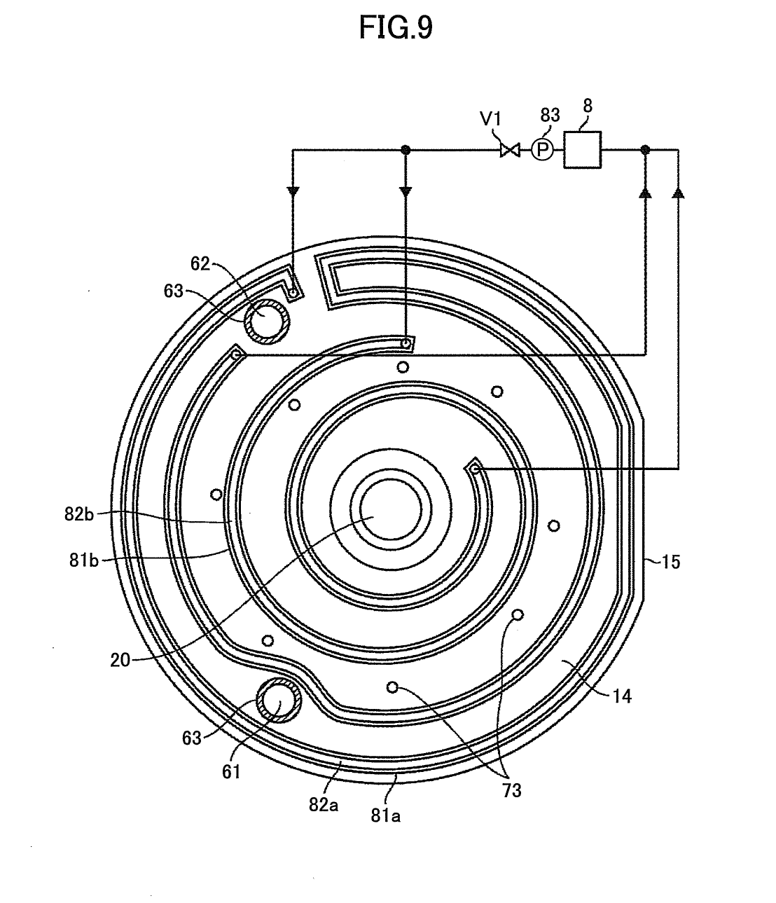

FIGS. 4A and 4B are diagrams illustrating the processing areas and the separation areas in the film deposition apparatus of this embodiment. As illustrated in FIG. 4A, the recess 24 is formed so that, when the wafer W is placed into the recess 24, the surface of the wafer is flush with the surface of the turntable 2 (the area where the wafer is not arranged). The pressure fluctuations produced due to the difference in the height between the surface of the wafer W and the surface of the turntable 2 can be suppressed and the uniformity of thickness within the surface of the deposited film can be attained. On the base part of the recess 24, through holes (not illustrated) are formed through which three lifting pins (refer to FIG. 9) penetrate. These lifting pins are used to support the bottom surface of the wafer W and move the wafer W up and down, in order to deliver the wafer W by a transport mechanism 10.

As illustrated in FIGS. 2 and 3, in order to respectively supply the first reactive gas, the second reactive gas, and the first separation gas to the substrate placement area of the recess 24 in the turntable 2, the first reactive gas supplying portion 31, the second reactive gas supplying portion 32, and the two first separation gas supplying portions 41 and 42 are arranged in the vacuum container 1 to respectively extend from mutually different positions of the circumference of the vacuum container 1 (or the circumference of the turntable 2) to the center of rotation of the turntable.

Each of the first reactive gas supplying portion 31, the second reactive gas supplying portion 32, and the first separation gas supplying portions 41 and 42 is constituted by a nozzle in which plural discharge holes for discharging the reactive gas or the separation gas are perforated on the bottom side of the nozzle and arranged at given intervals in the longitudinal direction of the nozzle.

For example, the first reactive gas supplying portion 31, the second reactive gas supplying portion 32, and the first separation gas supplying portions 41 and 42 are attached to the side wall of the vacuum container 1, and gas inlet ports 31a, 32a, 41a and 42a which are provided in the base end parts of the portions 31, 32, 41 and 42 respectively are arranged to penetrate the side wall of the vacuum container 1. In this embodiment, the gas inlet ports 31a, 32a, 41a and 42a are introduced from the side wall of the vacuum container 1.

Alternatively, the gas inlet ports 31a, 32a, 41a and 42a may be introduced from an annular projection 5 (which will be described later). In this case, an L-shaped conduit which includes first openings that are open to the circumferential side of the projection 5 and second openings that are open to the outside surface of the top plate 11 is provided in the vacuum container 1. Specifically, the first reactive gas supplying portion 31, the second reactive gas supplying portion 32 and the first separation gas supplying portions 41 and 42 are connected to the first openings of the L-shaped conduit in the interior of the vacuum container 1, and in the exterior of the vacuum container 1, the gas inlet ports 31a, 32a, 41a and 42a are connected to the second openings of the L-shaped conduit.

The reactive gas supplying portions 31 and 32 are connected to a gas supply source (not illustrated) of BTBAS gas (which is the first reactive gas) and a gas supply source (not illustrated) of O3 (ozone) gas (which is the second reactive gas), respectively. The separation gas supplying portions 41 and 42 are both connected to a gas supply source (not illustrated) of N2 gas (which is the separation gas). In this example, the second reactive gas supplying portion 32, the first separation gas supplying portion 41, the first reactive gas supplying portion 31, and the second separation gas supplying portion 42 are arranged clockwise in this order.

In each of the first reactive gas supplying portion 31 and the second reactive gas supplying portion 32, discharge holes 33 for discharging the first and second reactive gases are perforated on the bottom side of the gas supplying portion and arranged at given intervals in the longitudinal direction of the gas supplying portion. In each of the first separation gas supplying portions 41 and 42, discharge holes 40 for discharging the separation gas are perforated on the bottom side of the gas supplying portion and arranged at given intervals in the longitudinal direction of the gas supplying portion.

The area located below the reactive gas supplying portion 31 is a first processing area P1 for supplying the BTBAS gas to the wafer, and the area located below the reactive gas supplying portion 32 is a second processing area P2 for supplying the O3 gas to the wafer.

The separation gas supplying portions 41 and 42 are arranged to form a separation area D for separating the first processing area P1 and the second processing area P2. As illustrated in FIGS. 2-4B, the top plate 11 of the vacuum container 1 in this separation area D is provided with sector-form projecting portions 4 centering on the center of rotation of the turntable 2. The separation gas supplying portions 41 and 42 are disposed in the grooves 43 which are formed in the projecting portions 4 to extend in a radial direction from the center of rotation of the turntable 2. The distance from the centerline of the separation gas supplying portion 41 (42) and both side ends of the sector-form projecting portion 4 (both the upstream side end and the downstream side end thereof in the rotational direction) is set as being the same length. In this embodiment, the grooves 43 are formed to bisect the projecting portion 4. Alternatively, in another embodiment, the grooves 43 may be formed so that the upstream portion of the projecting portion 4 in the rotational direction of the turntable 2 is larger than the downstream portion of the projecting portion 4.

Therefore, a flat, low undersurface portion 44 (the first undersurface portion) which is an undersurface portion of the projecting portion 4 exists on both sides of each of the separation gas supplying portions 41 and 42 in the rotational direction, and an undersurface portion 45 (the second undersurface portion) which is higher than the undersurface portion 44 exists on both sides of the undersurface portion 44 in the rotational direction. The projecting portion 4 acts to form the separation space which is a narrow space for preventing entry of the first reactive gas and the second reactive gas into the space between the projecting portion 4 and the turntable 2, and for preventing mixing of these reactive gases.

For example, the separation gas supplying portion 41 prevents entry of O3 gas sent from the upstream side in the rotational direction of the turntable 2 and prevents entry of BTBAS gas sent from the downstream side in the rotational direction of the turntable 2. The “prevention of entry of gas” means that N2 gas, which is the separation gas discharged from the separation gas supplying portion 41, is spread between the first undersurface portion 44 and the surface of the turntable 2 and blown off, in this example, to the space below the second undersurface portion 45 adjacent to the first undersurface portion 44, thereby preventing entry of the gas from the adjoining space. The state in which entry of the gas is prevented does not mean the state in which all the gases from the first processing area P1 and the second processing area P2 do not enter the separation area D at all, but means the state in which some of the gases enter but the first reactive gas and the second reactive gas respectively entering from the left side and the right side are not mixed together in the separation area D. As long as these states are maintained, the operation of separating the atmosphere of the first processing area P1 and the atmosphere of the second processing area P2 by the separation area D is maintained. Because the gas which is absorbed into the wafer can pass through the inside of the separation area D, the gas entering from the adjoining space means the gas in the gaseous phase.

On the undersurface of the top plate 11, the annular projection 5 is formed along with the periphery of the core part 21 so that it faces the portion of the turntable 2 which is located outside the core part 21. This projection 5 is continuously formed with the central part of the projecting portion 4, and the undersurface of the projection 5 is formed to be the same height as the undersurface portion (the first undersurface portion 44) of the projecting portion 4. The cross sections of FIGS. 2 and 3 are illustrated by cutting the top plate 11 in the location that is lower than the undersurface portion 45 and higher than the separation gas supplying portions 41 and 42. The projection 5 and the projecting portion 4 may not necessarily be restricted to be the integral part, and they may be formed as separate parts.

The combined structure of the projecting portion 4 and the separation gas supplying portion 41 (42) may not necessarily be restricted to the illustrated embodiment. Alternatively, the projecting portion 4 and the separation gas supplying portion 41 (42) may be arranged using two sector-form plates such that the groove 43 and the projecting portion 4 are formed on each of the sector-form plates and the sector-form plates are secured to the undersurface portion of the top plate by bolts on both sides of the separation gas supplying portion 41 (42).

In the present embodiment, the aperture diameter of each of the discharge holes 40 in each of the separation gas supplying portions 41 and 42 is equal to about 0.5 mm, and the intervals at which the discharge holes 40 are arrayed along the longitudinal direction of the gas supplying portion (nozzle) are equal to about 10 mm. The aperture diameter of each of the discharge holes 33 in each of the reactive gas supplying portions 31 and 32 is equal to about 0.5 mm, and the intervals at which the discharge holes 33 are arrayed along the longitudinal direction of the gas supplying portion (nozzle) are equal to about 10 mm.

In the present embodiment, the wafer W with a diameter of 300 mm is used as the substrate being processed, and the circumferential length (the length of the arc of the circle coaxial to the circle of the turntable 2) of the first undersurface portion 44 at the projection 5 which is 140 mm distant from the center of rotation is set to 146 mm, and the circumferential length of the first undersurface portion 44 at the position of the outermost part of the recess 24 (substrate placement area) is set to 502 mm. As illustrated in FIG. 4A, the circumferential length L of the first undersurface portion 44 of the top plate 11 located at the end of the first separation gas supplying portion 41 (42) in the position of this outermost part is set to 246 mm.

As illustrated in FIG. 4A, the height h of the undersurface portion 44 of the projecting portion 4 from the surface of the turntable 2 is, for example, in a range between 0.5 mm and 10 mm. It is preferred that the height h is set to about 4 mm. In this case, the rotational speed of the turntable 2 is set in a range between 1 rpm and 500 rpm. In order to secure the separating function of the separation area D, the dimensions of the projecting portion 4 and the height h of the first undersurface portion 44 of the projecting portion 4 from the surface of the turntable 2 have to be set based on the experimental results according to the applicable rotational speed of the turntable 2.

The separation gas is not restricted to N2 gas.

Inert gas, such as Ar gas, may be used instead. Moreover, not only inert gas but also hydrogen gas may be used. The separation gas is not limited to a specific kind of gas, and if the gas does not affect the film deposition processing, the gas may be used suitably.

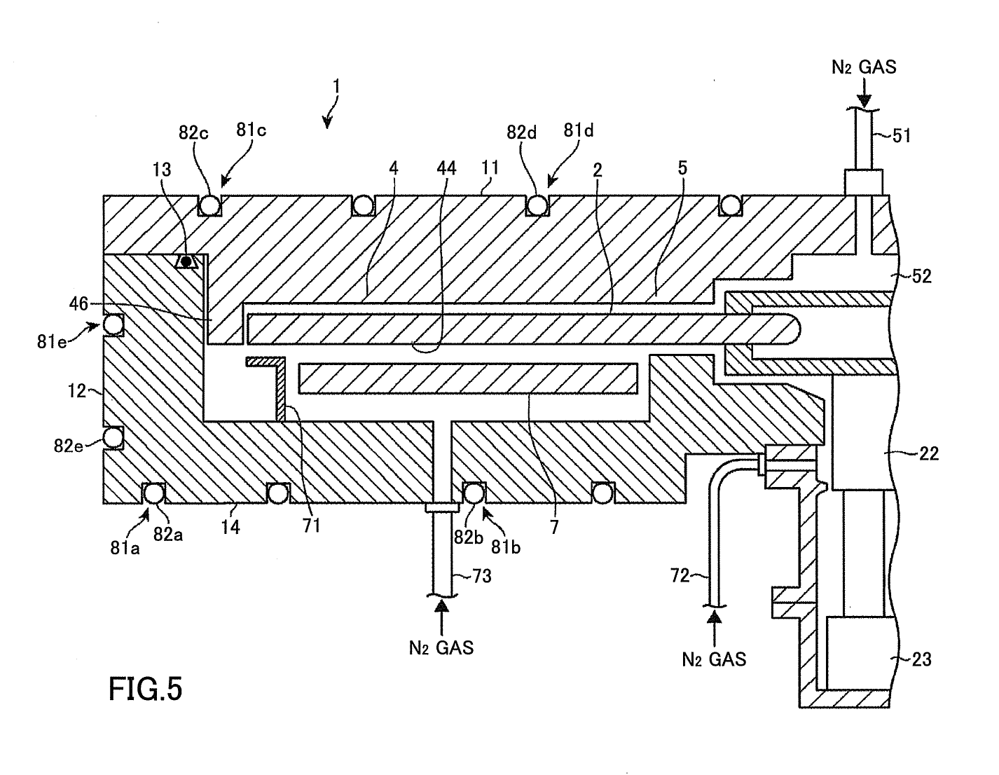

As described above, in the undersurface of the top plate 11 of the vacuum container 1, when viewed from the substrate placement area (the recess 24) of the turntable 2, both the first undersurface portion 44 and the second undersurface portion 45 higher than the undersurface portion 44 exist in the rotational direction of the turntable. FIG. 1 illustrates the cross section of the film deposition apparatus vertically cut in the area where the high undersurface portion 45 is arranged. FIG. 5 illustrates the cross section of the film deposition apparatus vertically cut in the area where the low undersurface portion 44 is arranged. As illustrated in FIGS. 2 and 5, the peripheral part of the sector-form projecting portion 4 (at the outer peripheral edge of the vacuum container 1) is bent into an L-shaped formation, and forms a curved portion 46 which faces the outer peripheral edge of the turntable 2. The sector-form projecting portion 4 is formed in the top plate 11 and is removable from the container main part 12. There is a slight gap between the peripheral surface of the curved portion 46 and the container main part 12. Similar to the projecting portion 4, the curved portion 46 is disposed to prevent entry of the reactive gas sent from the gas supplying portion and to prevent mixing of the first and second reactive gases. The gap between the inner peripheral surface of the curved portion 46 and the outer peripheral edge of the turntable 2 and the gap between the outer peripheral surface of the curved portion 46 and the container main part 12 are set to be the same dimension as the height h of the undersurface portion 44 from the surface of the turntable 2. In this example, the inner peripheral surface of the curved portion 46 constitutes the inner peripheral wall of the vacuum container 1 when viewed from the area of the upper surface of the turntable 2.

As illustrated in FIG. 5, the inner peripheral wall of the container main part 12 in the separation area D is formed into a vertical surface adjacent to the outer peripheral surface of the curved portion 46. However, in the area other than the separation area D, the inner peripheral wall of the container main part 12 has a depressed configuration extending from the portion facing the outer periphery of the turntable 2 to the base part 14, as illustrated in FIG. 1. This hollow portion will be called exhaust area 6. As illustrated in FIGS. 1 and 3, on the bottom of the exhaust area 6, two exhaust ports 61 and 62 are disposed. These exhaust ports 61 and 62 are respectively connected to a common vacuum pump 64 via an exhaust pipe 63. The vacuum pump 64 is an evacuation unit. In FIG. 1, reference numeral 65 denotes a pressure regulation unit. The pressure regulation unit 65 may be provided for each of the exhaust ports 61 and 62. Alternatively, one pressure regulation unit 65 may be provided in common for the exhaust ports 61 and 62.

The exhaust ports 61 and 62 are disposed on both sides of the separation area D in the rotational direction to ensure the separating function of the separation area D. The exhaust ports 61 and 62 are provided to exhaust the first and second reactive gases (BTBAS gas and O3 gas) individually. In this example, the exhaust port 61 is disposed between the first reactive gas supplying portion 31 and the separation area D located on the downstream side of the reactive gas supplying portion 31 in the rotational direction. The exhaust port 62 is disposed between the second reactive gas supplying portion 32 and the separation area D located on the downstream side of the reactive gas supplying portion 32 in the rotational direction.

The number of exhaust ports installed is not restricted to two. Additionally, a third exhaust port may be installed between the separation area D, including the first separation gas supplying portion 42, and the second reactive gas supplying portion 32 located on the downstream side of the separation area D in the rotational direction. Alternatively, four or more exhaust ports may be installed.

As illustrated in FIGS. 1, 2 and 6, a heating unit 7 which is a substrate heating unit is disposed in the space between the turntable 2 and the base part 14 of the vacuum container 1. The heating unit 7 is provided for heating the wafer (the substrate) on the turntable 2 through the turntable 2 to a predetermined temperature in accordance with the process parameters. A cover member 71 is disposed near the lower part side of the periphery of the turntable 2 to surround the overall periphery of the heating unit 7. The cover member 71 is provided to divide the atmosphere from the upper space of the turntable 2 to the exhaust area 6 and the atmosphere where the heating unit 7 is disposed. The upper end of the cover member 71 is outwardly bent in a flanged formation. By reducing the gap between the bent portion and the undersurface portion of the turntable 2, the bent portion of the cover member 71 prevents inclusion of the gas from the outside to the inside of the cover member 71.

The inner portion of the base part 14, located near the center of rotation and apart from the space where the heating unit 7 is disposed, is formed to approach the core part 21 of the turntable 2, and a narrow space is formed between the base part 14 and the core part 21. A narrow space is also formed between the base part 14 and the inner circumference side of the bore part for the rotary shaft 22 in which the base part 14 is penetrated. These narrow spaces are formed to communicate with the case body 20. In the case body 20, a purge gas supplying portion 72 is disposed and the purge gas supplying portion 72 supplies N2 gas (which is the purge gas) to the narrow space. In the base part of the vacuum container 1, purge gas supplying portions 73 are disposed at two or more positions below the heating unit 7 along the rotational direction, and these purge gas supplying portions 7 supply N2 gas (which is the purge gas) to the space where the heating unit 7 is arranged.

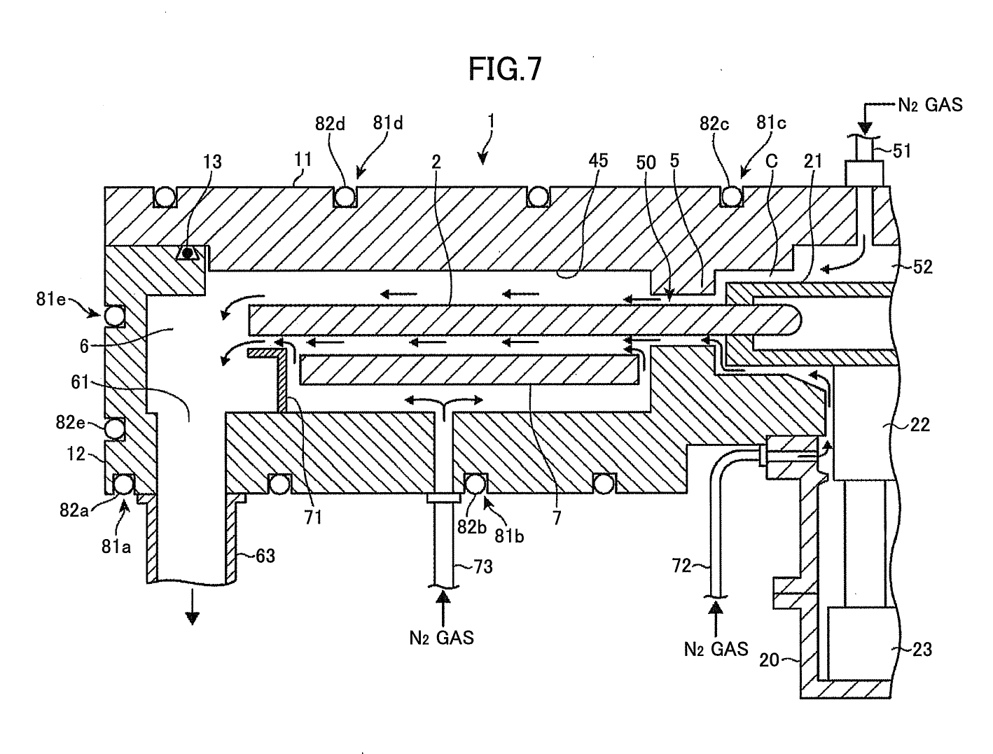

FIG. 7 illustrates the flow of the purge gas (N2 gas) by the purge gas supplying portions 72 and 73 as indicated by the arrows in FIG. 7. By forming the purge gas supplying portion 72 and the purge gas supplying portions 73, N₂ gas is supplied from the internal space of the case body 20 to the accommodating space of the heating unit 7, and N₂ gas from the space between the turntable 2 and the cover member 71 is exhausted to the exhaust ports 61 and 62 via the exhaust space 6. Because the flow of the first reactive gas (BTBAS gas) or the second reactive gas (O₃ gas) from one of the first processing area P1 and the second processing area P2 back to the other via the lower part of the turntable 2 is prevented, the purge gas functions as the separation gas to separate the first reactive gas and the second reactive gas.

A second separation gas supplying portion 51 penetrates the top plate 11 of the vacuum container 1, and is connected to the core of the vacuum container 1. The second separation gas supplying portion 51 supplies the separation gas (N₂ gas) to the central area C which is the space 52 between the top plate 11 and the core part 21.

The separation gas supplied to the central area C is discharged to the circumference along the surface on the side of the substrate placement area of the turntable 2 through the narrow space 50 between the projection 5 and the turntable 2. Because the space surrounded by the projection 5 is filled with the separation gas, mixing of the first reactive gas (BTBAS gas) and the second reactive gas (O₃ gas) is prevented through the core of the turntable 2 between the first processing area P1 and the second processing area P2. Namely, the film deposition apparatus is provided with the central area C which is surrounded by the center-of-rotation portion of the turntable 2 and the vacuum container 1 in order to separate the atmosphere of the first processing area P1 and the atmosphere of the second processing area P2, the separation gas is supplied to the central area C, and, in the central area C, the discharge hole which discharges the separation gas to the upper surface of the turntable 2 is disposed along the rotational direction. The discharge hole is equivalent to the narrow space 50 between the projection 5 and the turntable 2.

As illustrated in FIGS. 2, 3 and 8, a conveyance opening 15 for delivering the wafer W (or the substrate) between the external conveyance arm 10 and the turntable 2 is formed in the side wall of the vacuum container 1, and this conveyance opening 15 is opened and closed by the gate valve which is not illustrated. The delivery of the wafer W is performed between the recess 24 (which forms the substrate placement area of the turntable 2) and the conveyance arm 10 at the location which confronts the conveyance opening 15. The mechanism (not illustrated) for raising and lowering the lifting pins 16 (penetrating the recess 24) which lift the wafer from the rear surface thereof is disposed at the location corresponding to the delivery location on the side of the undersurface of the turntable 2.

As illustrated in FIGS. 1 and 9, a groove 81a and a groove 81b are formed in the peripheral portion and in the central portion, respectively, on the bottom surface of the base part 14 of the vacuum container 1 at locations other than the case body 20, the purge gas supplying portions 73 and the exhaust pipe 63 which are projected from the base part 14. The groove 81b is formed in a spiral configuration and the groove 81a is formed in the peripheral portion of the base part 14 to surround the outside of the groove 81b. In the grooves 81a and 81b, temperature control pipes 82a and 82b are disposed along the length directions of the grooves 81a and 81b respectively. A temperature control fluid, such as Galden (registered trademark), passes through the temperature control pipes 82a and 82b to perform heat exchange with the vacuum container 1 in order to carry out temperature control of the vacuum container 1. In this example, the temperature of the base part 14 is adjusted by the heat exchange between the temperature control fluid and the base part 14.

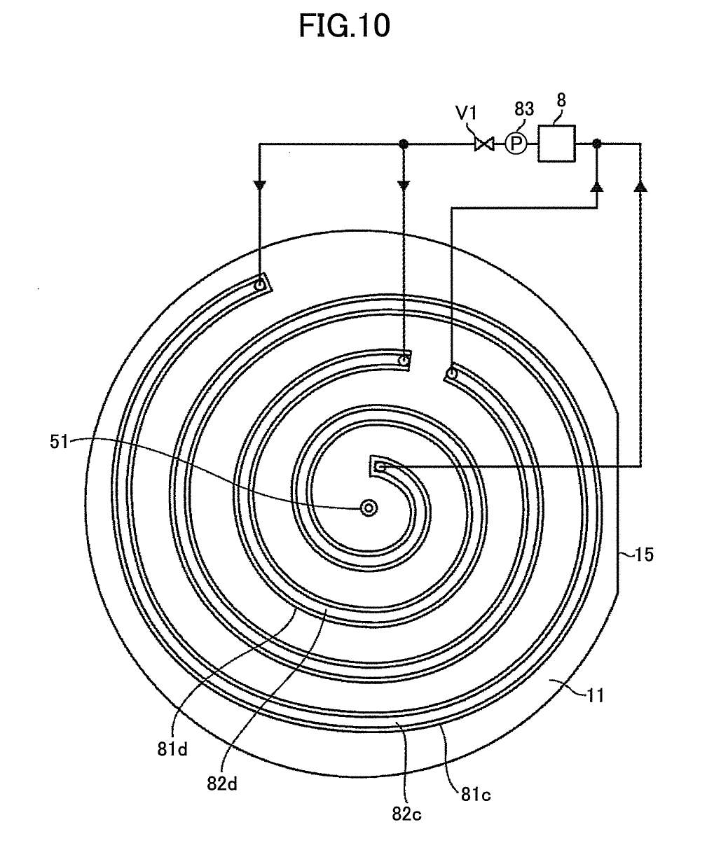

As illustrated in FIGS. 1 and 10, a groove 81c and a groove 81d are formed in a spiral configuration in the peripheral portion and in the central portion, respectively, on the top surface of the top plate 11 of the vacuum container 1, and temperature control pipes 82c and 82d are disposed in the grooves 81c and 81d along the length directions of the grooves 81c and 81d. Similar to the temperature control pipes 82a and 82b, a temperature control fluid, such as Galden, passes through the temperature control pipes 82c and 82d. In this example, the temperature of the top plate 11 is adjusted by the heat exchange between the temperature control fluid (Galden) and the top plate 11.

Furthermore, as illustrated in FIGS. 1 and 3, a groove 81e is formed in the side wall of the vacuum container 1 to surround the periphery of the vacuum container 1 from the upper part to the lower part, and a temperature control pipe 82e is disposed in the groove 81e along the length direction of the groove 81e. Similar to the temperature control pipes 82a-82d, a temperature control fluid, such as Galden, passes through the temperature control pipe 82e. In this example, the temperature of the side wall of the vacuum container 1 is adjusted by the heat exchange between the temperature control fluid (Galden) and the side wall. Each of the temperature control pipes 82a-82e is equivalent to a temperature control part in the claims.

The upstream portions of the temperature control pipes 82a and 82b of the base part 14 of the vacuum container 1, the temperature control pipes 82c and 82d of the top plate 11 of the vacuum container 1, and the temperature control pipe 82e of the side wall of the vacuum container 1 are extended out of the ends of the grooves 81a-81e and joined to a junction pipe, and the junction pipe is connected to a fluid temperature adjustment part 8 via a valve V1 and a pump 83. Opening and closing of the valve V1 and operation of the pump 83 are controlled by a control part 100.

The downstream portions of the temperature control pipes 82a-82e are extended out of the other ends of the grooves 81a-81e and joined to a junction pipe, and the junction pipe is connected to the fluid temperature adjustment part 8. The closed-loop circuit of the temperature control fluid is formed with the temperature control pipes 82a-82e and the fluid temperature adjustment part 8. The fluid temperature adjustment part 8 includes a storage tank, a cooling fluid passage, and a heating unit. The temperature control fluid is stored in the storage tank, and the upstream and downstream portions of the temperature control pipes 82a-82e are connected to the storage tank respectively. The cooling fluid passage is provided to cool the temperature control fluid by heat exchange with the temperature control fluid in the storage tank. The heating unit is provided to heat the temperature control fluid in the storage tank. The temperature of the temperature control fluid stored in the storage tank is controlled by the control part 100 which controls the flow rate of the cooling fluid and the electric power of the heating unit.

As illustrated in FIG. 1, the film deposition apparatus of this embodiment is provided with the control part 100, and this control part 100 includes a computer for controlling operation of the whole film deposition apparatus. A program which, when executed by the computer, causes the computer to perform the film deposition processing according to the invention is stored beforehand in the memory (not illustrated) of the control part 100. This program may be installed in the control part 100 from any of computer-readable storage media, such as a hard disk, a compact disc, a magnetic optical disk, a memory card, and a flexible disk, or may be downloaded from other equipment to the control part 100 at any time through a wired or wireless communication.

Moreover, the process parameters, including a controlled temperature of Galden for maintaining a temperature of the vacuum container 1 in a predetermined temperature range (for example, 80-100 degrees C.) according to a wafer heating temperature which is set by a user (or a process manager), are stored beforehand in the memory (not illustrated) of the control part 100. After the user sets up the wafer heating temperature using the input unit (which is not illustrated), the controlled temperature according to the wafer heating temperature set by the user is read from the memory of the control part 100 and a temperature of Galden stored in the fluid temperature adjustment part 8 is adjusted to the controlled temperature read from the memory of the control part 100. Because BTBAS gas is used in this embodiment, it is necessary that the temperature of the vacuum container 1 be maintained in the predetermined temperature range in which the BTBAS gas within the vacuum container 1 does not liquefy and the durability of the vacuum container 1 be maintained in an appropriate level.

Next, operation of the film deposition apparatus of the above-mentioned embodiment will be described.

First, the user inputs the wafer heating temperature using the input unit (not illustrated). At this time, the temperature of the vacuum container 1 is, for example, about 40 degrees C. After the wafer heating temperature is input by the user, a controlled temperature of Galden according to the wafer heating temperature is read from the memory of the control part 100. The electric power of the heating unit and the flow rate of the cooling fluid in the fluid temperature adjustment part 8 are controlled, so that the temperature of Galden stored in the fluid temperature adjustment part 8 is adjusted to the controlled temperature read from the memory of the control part 100. Suppose that in this example of the film deposition processing, the heating temperature of the wafer W is set to 350 degrees C. and the temperature of Galden stored in the fluid temperature adjustment part 8 is adjusted to 90 degrees C. (or the controlled temperature for this example).

Subsequently, the valve V1 is opened and the pump 83 operates to cause the Galden, the temperature of which is adjusted to the controlled temperature, to pass through the temperature control pipes 82a-82e in the downstream direction. The Galden flows through each surface of the top plate 11, the base part 14 and the side walls of the vacuum container 1, and the heat of the Galden is given to these parts of the vacuum container 1, so that the temperature of the vacuum container 1 is raised. Then, the Galden is cooled and returned back to the temperature control part 8. Again, the temperature control of the Galden to 90 degrees C. is carried out, and then the Galden flows through the temperature control pipes 82a-82e in the downstream direction.

Subsequently, the temperature of the heating unit 7 is made to rise and the turntable 2 is heated by the heating unit 7. The vacuum container 1 receives the thermal radiation from the heating unit 7, and the temperature of the vacuum container 1 rises further.

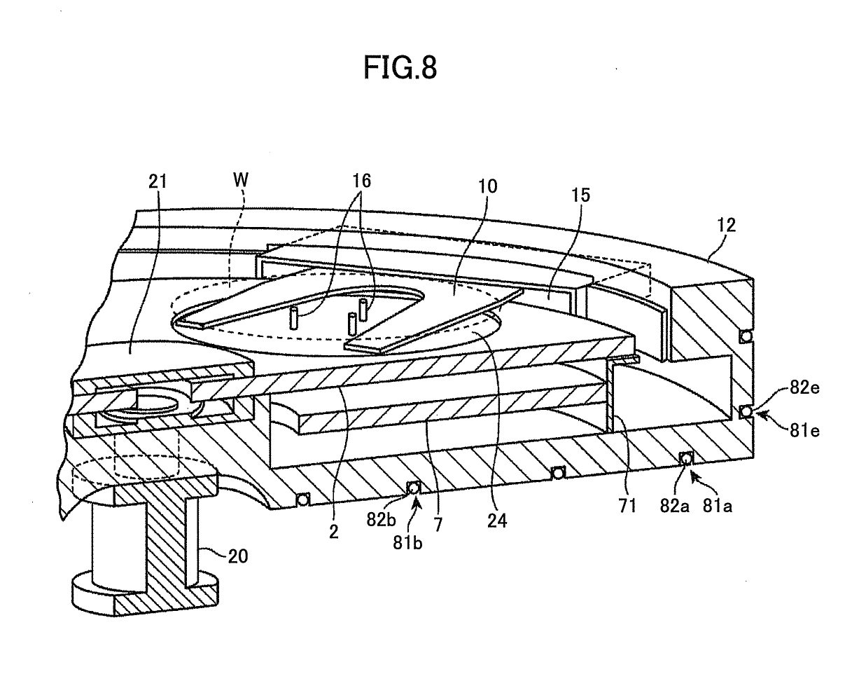

Subsequently, the gate valve (not illustrated) is opened and a wafer W from the exterior is delivered to the recess 24 of the turntable 2 via the conveyance opening 15 by the conveyance arm 10. This delivery is performed when the rotation of the turntable 2 is stopped at the location where the recess 24 faces the conveyance opening 15. As illustrated in FIG. 8, the lifting pins 16 raised from the bottom side of the vacuum container 1 through the through holes on the bottom of the recess 24 at this location are lowered so that the wafer W is placed in the recess 24.

The delivery of the wafer W is repeatedly performed while the turntable 2 is rotated intermittently, and the wafers W are placed in the five recesses 24 of the turntable 2 respectively. Then, evacuation is carried out by the vacuum pump 64 and the pressure inside the vacuum container 1 is set to a predetermined vacuum pressure. At the same time, the turntable 2 is rotated clockwise. After it is checked by using a temperature sensor (not illustrated) that the temperature of the wafer W reaches 350 degrees C. (which is the preset wafer heating temperature), BTBAS gas and O3 gas are discharged from the first reactive gas supplying portion 31 and the second reactive gas supplying portion 32, respectively. At the same time, N2 gas (which is the separation gas) is discharged out from each of the separation gas supplying portions 41 and 42. At this time, the temperature of the vacuum container 1 is maintained in the predetermined temperature range (which is, for example, the temperature range of 80-100 degrees C.) by the thermal radiation from the heating unit 7 and the flow of the Galden (or the temperature control fluid).

By the rotation of the turntable 2, the wafer W passes by the first processing area P1 where the first reactive gas supplying portion 31 is disposed and the second processing area P2 where the second reactive gas supplying portion 32 is disposed alternately. The BTBAS gas is first absorbed by the wafer W and then the O3 gas is absorbed by the wafer W. In this manner, the BTBAS molecules oxidize and one or more molecular layers of oxidation silicone are formed on the wafer W, so that the molecular layers of oxidation silicone are laminated one by one. As a result, a silicone oxide film with a predetermined thickness is formed on the wafer W.

At this time, N2 gas (which is the separation gas) is supplied also from the separation gas supplying portion 51, and the N2 gas is discharged from the central area C (or the area between the projection 5 and the center of the turntable 2) along the surface of the turntable 2. In this example, the inner peripheral wall of the container main part 12 along the space beneath the second undersurface portion 45 where the reactive gas supplying portions 31 and 32 are arranged is cut away to form a comparatively wide space. The exhaust ports 61 and 62 are located beneath the wide space, and the pressure in the wide space located beneath the second undersurface portion 45 is lower than the pressure in each of the narrow space located beneath the first undersurface portion 44 and the space located beneath the central area C.

FIG. 7 illustrates the condition of the flow of the N2 gas when the N2 is discharged from the respective gas supplying portions. The O3 gas, which is discharged downward from the second reactive gas supplying portion 32 and hits the surface of the turntable 2 (which includes both the surface of the wafer W and the surface of the area of the turntable 2 where the wafer W is not arranged), is directed toward the upstream portion in the rotational direction of the turntable along the surface of the turntable 2. This O3 gas is pushed back by the N2 gas from the upstream direction and flows into the exhaust area 6 between the peripheral end of the turntable 2 and the inner peripheral wall of the vacuum container 1, so that the O3 gas is exhausted from the exhaust port 62.

The O3 gas, which is discharged downward from the second reactive gas supplying portion 32, hits the surface of the turntable 2, and is directed toward the downstream portion in the rotational direction of the turntable 2 along the surface of the turntable 2, tends to go to the exhaust port 62 by the flow of the N2 gas discharged from the central area C and the intake action of the exhaust port 62. Part of this O3 gas is directed toward the separation area D located adjacent to the downstream portion, and tends to flow into the space beneath the sector-folio projecting portion 4. However, the height and the peripheral-direction length of the undersurface portion 44 of the projecting portion 4 are set to such dimensions that are able to prevent the entry of the O3 gas into the space beneath the undersurface portion 44 when the process parameters including the flow rates of the respective gases are used at the time of operation. As illustrated in FIG. 4B, the O3 gas can hardly flow into the space beneath the sector-form projecting portion 4, and even if the O3 gas flows into the space temporarily, it cannot arrive at the area in the neighborhood of the separation gas supplying portion 41. The O3 gas is also pushed back to the upstream portion (or the processing area P2) in the rotational direction of the turntable 2 by the N2 gas discharged from the separation gas supplying portion 41. The O3 gas flows into the exhaust area 6 between the peripheral end of the turntable 2 and the inner peripheral wall of the vacuum container 1, so that the O3 gas is exhausted from the exhaust port 62 together with the N2 gas discharged from the central area C.

The BTBAS gas, which is discharged downward from the first reactive gas supplying portion 31 and directed to each of the upstream portion and the downstream portion in the rotational direction of the turntable 2 along the surface of the turntable 2, cannot enter the space beneath the sector-form projecting portion 4 which is located adjacent to each of the upstream portion and the downstream portion in the rotational direction of the turntable 2. Even if the BTBAS gas flows into the space temporarily, the BTBAS gas is pushed back to the second processing area P1 and sent to the exhaust area 6 between the peripheral end of the turntable 2 and the inner peripheral wall of the vacuum container 1, so that the BTBAS gas is exhausted from the exhaust port 61 via the exhaust area 6 together with the N2 gas discharged from the central area C. Namely, entry of the BTBAS gas and the O3 gas which are the reactive gases flowing in the atmospheres in the separation areas D is prevented, but only the gas molecules absorbed by the wafer W pass through the space beneath the separation areas (i.e., the low undersurface portions 44 of the sector-form projecting portions 4), and contribute to the film deposition processing.

Furthermore, the BTBAS gas in the first processing area P1 (and the O3 gas in the second processing area P2) tends to enter the central area C. However, the separation gas is discharged from the central area C towards the peripheral end of the turntable 2 as illustrated in FIGS. 7 and 9. Entry of the BTBAS gas and the O3 gas is prevented by this separation gas, or even if part of the reactive gases flows into the central area C, the reactive gases are pushed back by the separation gas, and entry of the reactive gases into the first processing area P1 and the second processing area P2 through the central area C is prevented.

In the separation areas D, the peripheral ends of the sector-form projecting portions 4 are bent downward to form the narrow space between the curved portion 46 and the outer peripheral end of the turntable 2, the passage of gas is substantially inhibited. Hence, entry of the BTBAS gas in the first processing area P1 (or the O3 gas in the second processing area P3) into the second processing area P2 (or into the first processing area P1) via the outside of the turntable 2 is prevented. Therefore, the atmosphere in the first processing area P1 and the atmosphere in the second processing area P2 are completely separated from each other by the two separation areas D, and the BTBAS gas and the O3 gas are exhausted from the exhaust port 61 and the exhaust port 62, respectively.

As a result, both the reactive gases (in this example, BTBAS gas and O3 gas) are not mixed on the wafer and in the atmospheres. In this example, the lower portions of the turntable 2 are purged by the N2 gas, and there is no possibility that the BTBAS gas flowing into the exhaust area 6 may pass through the lower portions of the turntable 2 and flow into the area in which the O3 gas is discharged to the wafer. After the film deposition processing is completed in this way, each wafer is delivered to the exterior out of the film deposition apparatus by the conveyance arm 10 one by one in the outgoing delivery sequence that is the reverse of the incoming delivery sequence.

Next, an example of the process parameters will be described. For example, when a wafer W with the diameter of 300 mm is used as a substrate to be processed, the rotational speed of the turntable 2 is set to a rotational speed in a range of 1 rpm and 500 rpm, the process pressure is set to 1067 Pa (8 Torr), and the heating temperature of the wafer W is set to 350 degrees C. For example, the flow rates of BTBAS gas and O₃ gas are set to 100 sccm and 10000 sccm respectively. For example, the flow rate of N₂ gas from the separation gas supplying portion 41 or 42 is set to 20000 sccm, and the flow rate of N₂ gas from the separation gas supplying portion 51 of the core of the vacuum container 1 is set to 5000 scum. For example, the number of cycles of the supply of the reactive gases to one wafer (or the number of times in which the wafer passes by each of the first processing area P1 and the second processing area P2) is set to 600 cycles, although it may vary depending on the target film thickness.

In the previously described example, the heating temperature of the wafer W is set to 350 degrees C. and the vacuum container 1 is heated by the temperature control fluid passing through the temperature control pipes 82a-82e. Next, another case in which the user sets the heating temperature of the wafer W to 600 degrees C. and the vacuum container is cooled by the temperature control fluid passing through the temperature control pipes 82a-82e will be explained.

In the present case, after the wafer heating temperature (which is, in this case, 600 degrees C.) is input by the user, the temperature of Galden stored in the fluid temperature adjustment part 8 is adjusted to 90 degrees C. (which is the controlled temperature according to the wafer heating temperature in this case) by the control part 100.

Subsequently, the valve V1 is opened and the pump 83 operates to cause the Galden, the temperature of which is adjusted to the controlled temperature, to pass through the temperature control pipes 82a-82e in the downstream direction.

Subsequently, the temperature of the heating unit 7 is made to rise and the turntable 2 is heated by the heating unit 7. The vacuum container 1 receives the thermal radiation from the heating unit 7, and the temperature of the vacuum container 1 rises further.

In this case, the Galden, which flows through each surface of the top plate 11, the base part 14 and the side walls of the vacuum container 1, serves to cool these parts of the vacuum container 1. Then, the Galden is heated by the heat from these parts of the vacuum container 1 (the top plate 11, the base part 14 and the side walls) and returned back to the temperature control part 8. Again, the Galden is cooled to 90 degrees C. in the temperature control part 8 and flows through the temperature control pipes 82a-82e in the downstream direction.

Subsequently, a wafer W from the exterior is delivered to the turntable 2 as previously described, and evacuation is carried out by the vacuum pump 64 so that the pressure inside the vacuum container 1 is set to the predetermined vacuum pressure. After it is checked by using the temperature sensor (not illustrated) that the temperature of the wafer W reaches 600 degrees C. (which is the preset wafer heating temperature), BTBAS gas and O3 gas are discharged from the reactive gas supplying portions 31 and 32 respectively, and N2 gas is discharged from the separation gas supplying portions 41 and 42. At this time, the temperature of the vacuum container 1 is maintained in the predetermined temperature range (which is, for example, the temperature range of 80-100 degrees C.) by the thermal radiation from the heating unit 7 and the flow of the Galden (or the temperature control fluid). After this, operation of the film deposition processing progresses in the manner which is the same as in the previous case in which the wafer heating temperature is set to 350 degrees C.

The film deposition apparatus of the above-described embodiment includes: the turntable 2 disposed in the vacuum container 1 includes the substrate placement area in which a wafer W is placed; the heating unit 7 disposed to heat the wafer W placed in the turntable 2; the first and second reactive gas supplying portions 31 and 32 disposed over the turntable 2 to respectively supply BTBAS gas and O3 gas to the first and second processing areas P1 and P2 where the film deposition processing is carried out; the separation gas supplying portions 41 and 42 disposed over the turntable 2 to supply the separation gas to the separation area D; and the temperature control pipes 82a-82e arranged to heat or cool the vacuum container 1 by the temperature control fluid passing through the temperature control pipes 82a-82e. Therefore, the use of the temperature control pipes 82a-82e effectively prevents the heating temperature of the wafer W from affecting the temperature of the vacuum container 1. Specifically, when the heating temperature of the wafer W is high, it is possible to prevent the temperature of the vacuum container 1 from becoming too high, which thereby prevents the durability of the film deposition apparatus from deteriorating. On the other hand, when the heating temperature of the wafer W is low, it is possible to prevent the BTBAS gas discharged from the reactive gas supplying portion 31 from liquefying, which thereby prevents the film deposition processing from being performed abnormally, or prevents the quality of the film formed on the wafer W from deteriorating.

In the film deposition apparatus of the above-described embodiment, the temperature control pipes 82a-82e are arranged in the top plate 11, the base part 14 and the side walls of the vacuum container 1, respectively. However, the film deposition apparatus according to the invention is not limited to the specifically disclosed embodiment, and the layout or arrangement of the temperature control pipes is not restricted to the above-described embodiment.

In the film deposition apparatus of the above-described embodiment, the wafers W are arranged in the peripheral direction of the turntable 2, and the top plate 11 and the base part 14 of this film deposition apparatus are larger in size than those of a film deposition apparatus on which one wafer is arranged and the film deposition processing of the wafer is performed. As a result, the heat dissipation from the top plate 11 and the base part 14 of the film deposition apparatus of the above-described embodiment becomes large, and the temperature of the top plate 11 and the base part 14 may easily become high during the film deposition processing. Therefore, the temperature control pipes 82a-82d which are arranged in the top plate 11 and the base part 14 as in the above-described embodiment, to cool the top plates 11 and the base part 14 when the heating temperature of the wafer W is set to a high temperature, are effective in lowering the temperature of the vacuum container 1.

Besides the above-mentioned example, the reactive gases that may be used in the film deposition apparatus according to the invention are dichlorosilane (DCS), hexachlorodisilane (HCD), trimethyl aluminum (TMA), tetrakis-ethyl-methyl-amino-zirconium (TEMAZr), tris(dimethyl amino) silane (3DMAS), tetrakis-ethyl-methyl-amino-hafnium (TEMHf), bis(tetra methyl heptandionate) strontium (Sr(THD)₂), (methyl-pentadionate)(bis-tetra-methyl-heptandionate) titanium (Ti(MPD)(THD)), monoamino-silane, or the like.

According to the film deposition apparatus of the above-described embodiment, it is possible to prevent liquefying and solidifying of the reactive gas within the vacuum container 1, and the above-described embodiment is effective for a film deposition apparatus which uses a reactive gas in its evaporated state.

In the film deposition apparatus of the above-described embodiment, Galden is used as the temperature control fluid passing through the temperature control pipes 82a-82e. Alternatively, instead of Galden, a cooling fluid, such as cooling water or Peltier elements, may be used as the temperature control fluid passing through the temperature control pipes 82a-82e to cool the vacuum container 1 by the heat exchange between the cooling fluid and the vacuum container 1. Additionally, in such an alternative embodiment, heating of the vacuum container 1 may be performed by using a plurality of heaters which are the heating units arranged in the vacuum container 1.

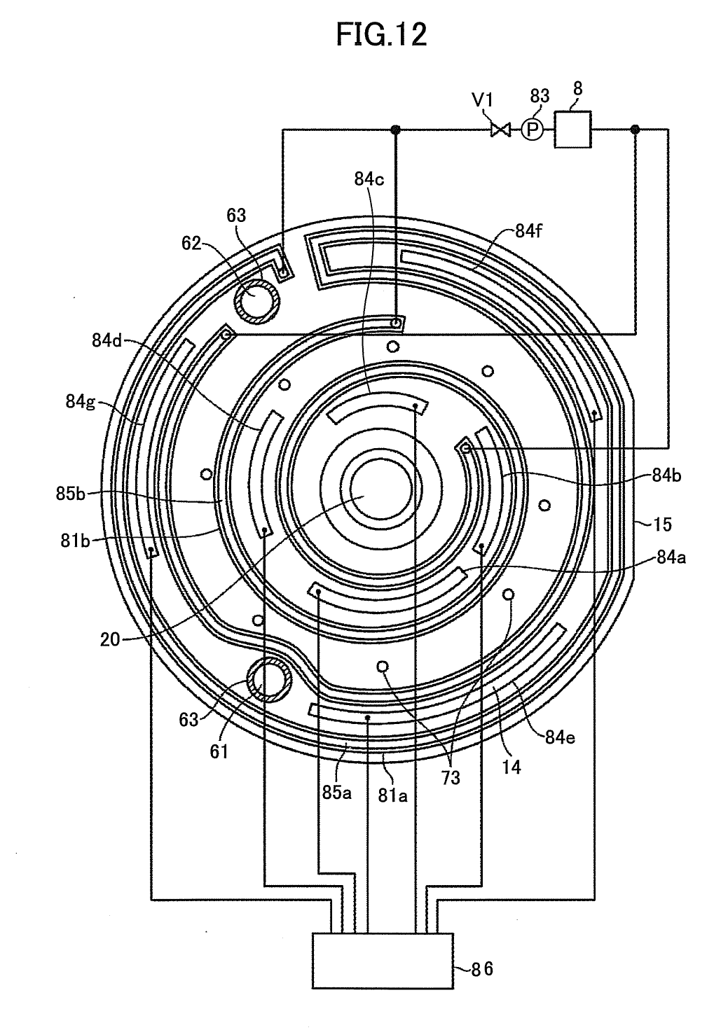

FIG. 12 illustrates the composition of a base part 14 in a modification of the film deposition apparatus of the above-described embodiment. In this base part 12, a plurality of heaters 84a-84g (which are illustrated by the plate-like configurations in FIG. 12) and a pair of temperature control pipes 85a and 85b are arranged. Each of the heaters 84a-84g is made of a heating wire. The temperature control fluid passing through the pipes 85a and 85b is a cooling fluid, such as cooling water, instead of Galden in the previously described embodiment. However, the composition of the pipes 85a and 85b arranged for cooling in this embodiment is essentially the same as the composition of the pipes 82a and 82b arranged for temperature control in the previously described embodiment.

In the base part 12 illustrated in FIG. 12, a fluid temperature adjustment part 8, which is arranged instead of the fluid temperature adjustment part 8 in the previously described embodiment, is the same as the known chiller unit according to the related art. This fluid temperature adjustment part 8 includes a storage tank for storing the cooling fluid, and a cooling unit for cooling the cooling fluid stored in the storage tank by heat exchange.

In FIG. 12, reference numeral 86 denotes an electric power controller. This electric power controller 86 controls the electric power supplied to each of the heaters 84a-84g in response to a control signal received from the control part 100. The fluid temperature adjustment part 8 of this embodiment is arranged in the base part 14 of the vacuum container 1. Alternatively, this fluid temperature adjustment part 8 may be arranged in the top plate 11 or the side wall of the vacuum container 1.

When the cooling pipes are arranged in the vacuum container 1, the known heating mantle according to the related art may be arranged as a heating unit. If the known heating mantle is used, it is effective to prevent the temperature of the vacuum container 1 from becoming too high by using the heating mantle which controls the temperature of the cooling fluid passing through the cooling pipes.

It is preferred that the width of the outer peripheral area of the undersurface portion 44 of the separation area D at the upstream part in the rotational direction of the turntable 2 is as large as possible. By the rotation of the turntable 2, the speed of the flow of the gas discharged by the separation gas supplying portions 41 and 42 and directed from the upstream part in the rotational direction of the turntable 2 to the separation area D is highest at the outer peripheral area. From the viewpoint of increasing the width of the outer peripheral area, the provision of the sector-form projecting portion 4 as described above is desirable.

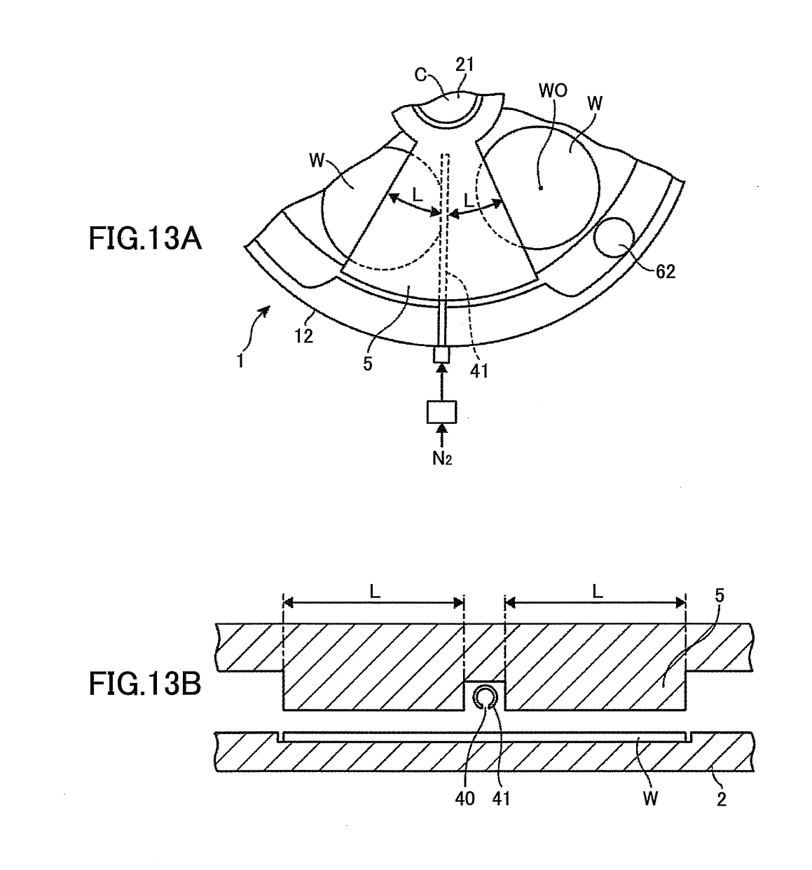

When the wafer W with the diameter of 300 mm is used, it is preferred that the first undersurface portion 44 which forms the narrow space on both sides of the separation gas supplying portion 41 (42) has a width dimension L of 50 mm or larger at the portion where the center WO of the wafer W passes along the rotational direction of the turntable 2 as illustrated in FIGS. 13A and 13B (in which the separation gas supplying portion 41 is typically illustrated). When the width dimension L is small, it is necessary to make the distance between the first undersurface portion 44 and the turntable 2 small in accordance with the small width dimension L, in order to prevent effectively entry of the reactive gas to the space beneath the projecting portion 4 (the narrow space) from the both sides of the projecting portion 4. The rotational speed of the turntable 2 is highest at the outer peripheral end thereof. If the distance between the first undersurface portion 44 and the turntable 2 is set to a certain dimension, the width dimension L of the first undersurface portion 44 needed for the outer peripheral end of the turntable 2 must be large enough to prevent effectively entry of the reactive gas to the space beneath the projecting portion 4.

If the width dimension L of the first undersurface portion 44 at the portion where the center WO of the wafer W passes along the rotational direction of the turntable 2 is smaller than 50 mm, it is necessary to make the distance of the first undersurface portion 44 and the turntable 2 very small. In this case, in order to prevent the collision between the turntable 2 or the wafer W and the undersurface portion 44 when the turntable 2 is rotated, a certain mechanism for reducing the vibrations of the turntable 2 as much as possible must be arranged additionally. When the rotational speed of the turntable 2 is high, the reactive gas from the upstream side of the projecting portion 4 easily enters the space beneath the projecting portion 4. For this reason, if the width dimension L is smaller than 50 mm, the rotational speed of turntable 2 must be made as low as possible, and in such a case, it is difficult to obtain high throughput. Although it is preferred that the width dimension L is 50 mm or larger, the advantageous effect of the invention may be acquired even when the width dimension L is 50 mm or smaller. In other words, it is preferred that the width dimension L is in a range between 1/10and 1/1of the diameter of the wafer W, and it is more preferred that it is equal to about ⅙ of the wafer W or larger.

Next, a description will be given of the composition of film deposition apparatuses of other embodiments of the invention which differ from the previously described embodiment with respect to the layout of the processing areas P1, P2 and the separation area D.

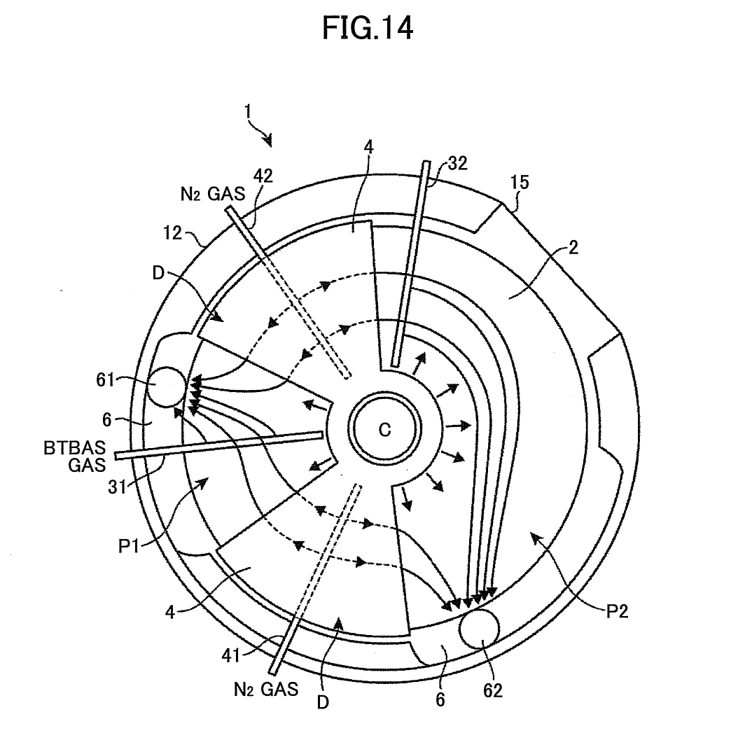

FIG. 14 is a plan view of a film deposition apparatus of another embodiment of the invention in the state where the top plate 11 of the vacuum container 1 is separated. The film deposition apparatus of this embodiment is different from the film deposition apparatus of the previously described embodiment in that the second reactive gas supplying portion 32 is disposed upstream of the conveyance port 15 in the rotational direction of the turntable 2, as illustrated in FIG. 14.

In the film deposition apparatus of this embodiment having such a layout, the first reactive gas and the second reactive gas can be separated more efficiently by the separation gas, infiltration of the first separation gas to the second undersurface portion 45 can be prevented, and the first reactive gas and the second reactive gas can be supplied to the wafer in the second undersurface portion 45 more efficiently.

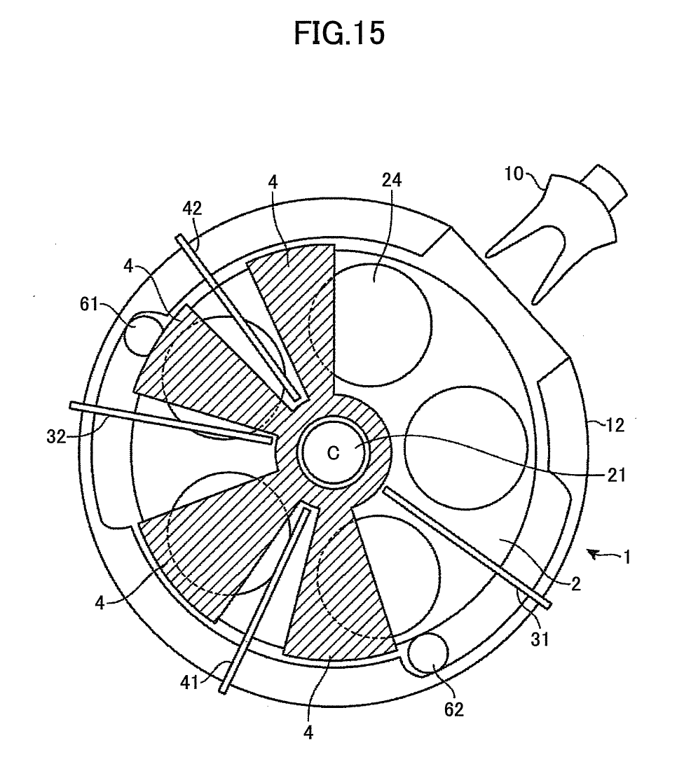

The separation area D may be divided into two sector-form projecting portions 4 in the peripheral direction and the separation gas supplying portion 41 (42) may be disposed between the projecting portions 4. FIG. 15 is a plan view illustrating the composition of the film deposition apparatus of another embodiment of the invention having such a structure. In this case, the magnitude of the sector-form projecting portion 4 and the distance between the projecting portion 4 and the separation gas supplying portion 41 (42) is set by taking into consideration the discharge flow rate of the separation gas, the discharge flow rate of the reactive gas, etc., so that the separation area D can provide effective segregation.

In the above-mentioned embodiment, the first processing area P1 and the second processing area P2 are equivalent to the areas where the undersurface portion thereof is higher than the undersurface portion of the separation area D. Alternatively, at least one of the first processing area P1 and the second processing area P2 may be similar to the separation area D. Namely, at least one of the first processing area P1 and the second processing area P2 may be disposed to face the turntable 2 at the location on both sides of the reactive gas supplying unit in the rotational direction and to form the space for preventing entry of gas into the turntable 2. At least one of the first processing area P1 and the second processing area P2 may have the undersurface portion the height of which is the same as that of the first undersurface portion 44 of the separation area D, and is lower than the undersurface portion (the second undersurface portion 45) of the separation area D.

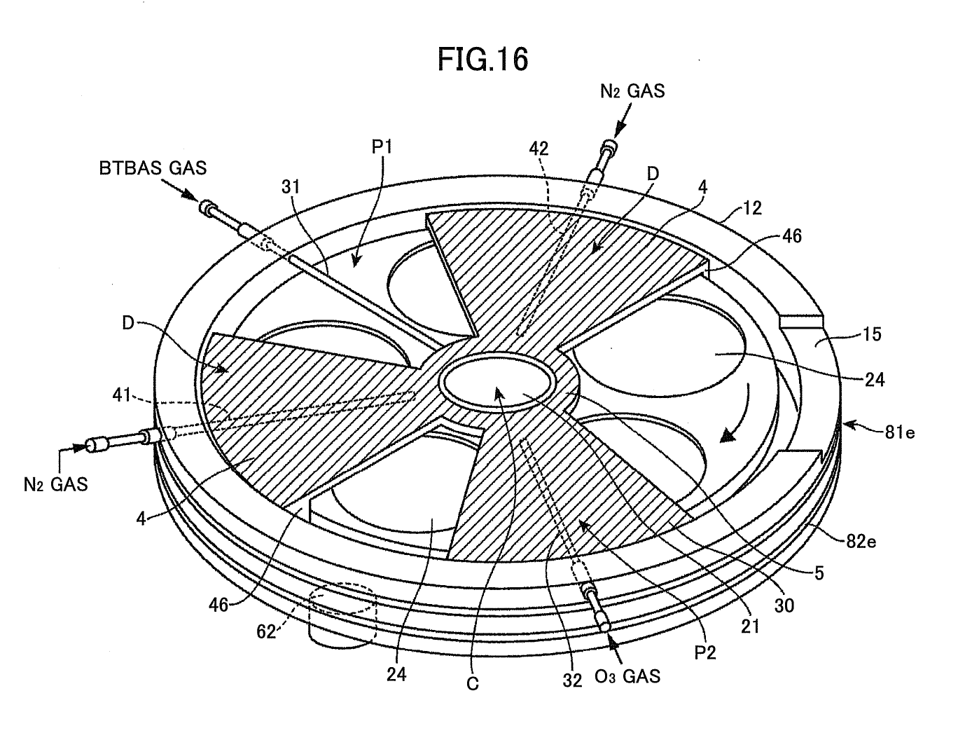

FIG. 16 is a perspective view illustrating the composition of the film deposition apparatus of another embodiment which has such structure. The film deposition apparatus of this embodiment is arranged so that the second reactive gas supplying portion 32 is disposed below the sector-form projecting portion 30 in the second processing area P2 (which is, in this example, the O3 gas absorbing area). The second processing area P2 is essentially the same as the separation area D except that the second reactive gas supplying portion 32 is arranged instead of the separation gas supplying portion 41 (42).

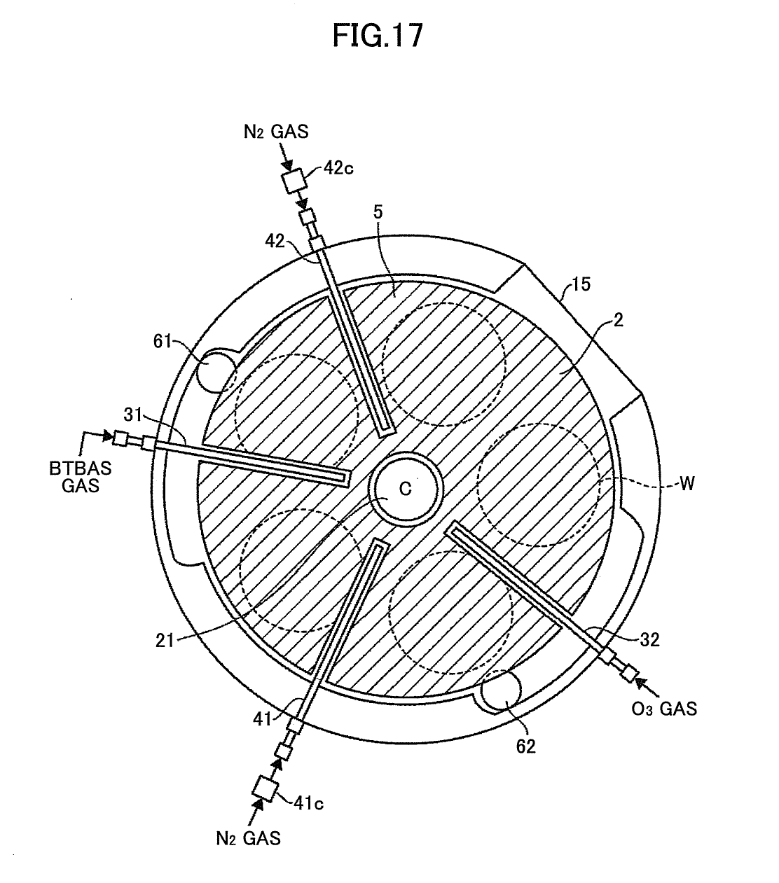

It is necessary that the low undersurface portion (the first undersurface portion 44) is arranged in order to form the narrow space on the both sides of the separation gas supplying portion 41 (42). However, as illustrated in FIG. 17, a low undersurface portion that is the same as the first undersurface portion 44 may be additionally arranged on the both sides of the reactive gas supplying portion 31 (32). These undersurface portions may be formed integrally. In the composition of FIG. 17, the projecting portion 4 is formed in the whole area to face the turntable 2, except for the locations where the separation gas supplying portion 41 (42) and the reactive gas supplying portion 31 (32) are disposed. In this composition, the first undersurface portion 44 on the both sides of the separation gas supplying portion 41 (42) is extended to the area of the reactive gas supplying portion 31 (32). In this case, the separation gas is spread over both sides of the separation gas supplying portion 41 (42), the reactive gas is spread over both sides of the reactive gas supplying portion 31 (32), and these gases reach the lower part side (narrow space) of the projecting portion 4. However, these gases will be exhausted from the exhaust port 61 (62) located between the separation gas supplying portion 31 (32) and the reactive gas supplying portion 42 (41).

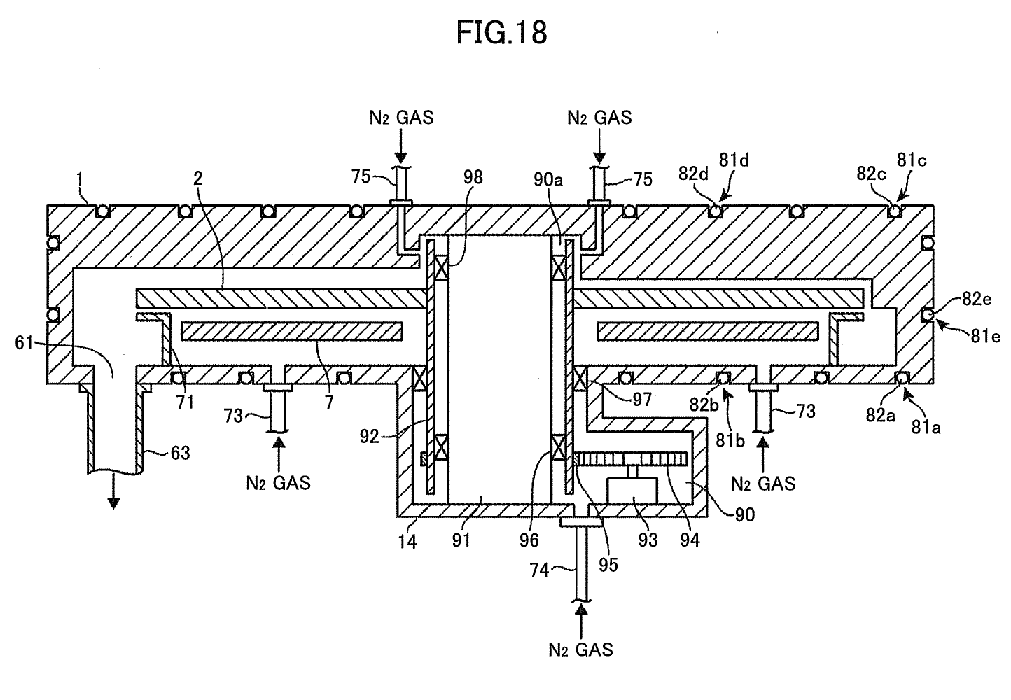

In the above embodiments, the rotation shaft 22 of the turntable 2 is located in the central part of the vacuum container 1 and the separation gas is purged to the space between the central part of the turntable 2 and the upper surface of the vacuum container 1. Alternatively, the film deposition apparatus according to the invention may be arranged as illustrated in FIG. 18. FIG. 18 is a cross-sectional view illustrating the composition of a film deposition apparatus of another embodiment of the invention.

In the film deposition apparatus of FIG. 18, the base part 14 of the center region of the vacuum container 1 is projected downward to form an accommodation space 90 of the drive part. As illustrated in FIG. 18, a recess 90a is formed in the upper surface of the central region of the vacuum container 1, and a support 91 is disposed in the core of the vacuum container 1 between the bottom of the accommodation space 90 and the upper surface of the recess 90a.

As illustrated in FIG. 18, the base part 14 of the center region of the vacuum container 1 is projected downward to form the accommodation space 90 of the drive part. The recess 90a is formed in the upper surface of the center region of the vacuum container 1, and the support 91 is interposed between the bottom of the accommodation space 90 and the upper surface of the recess 90a in the core of the vacuum container 1 in order to prevent the BTBAS gas from the first reactive gas supplying portion 31 and the O₃ gas from the second reactive gas supplying portion 32 from being mixed together in the core of the vacuum container 1.

As the drive mechanism which rotates the turntable 2, the rotation sleeve 92 is arranged to surround the support 91, and the turntable 2 is arranged along the rotation sleeve 92. The drive gear parts 94 and 95 which are driven by the motor 93 are arranged in the accommodation space 90, and these drive gear parts 94 and 95 rotate the rotation sleeve 92. In FIG. 18, reference numerals 96, 97 and 98 denote bearings.

The purge gas supplying portion 72 that supplies the purge gas is connected to the bottom of the accommodation space 90, and the second separation gas supplying portion 51 that supplies the second separation gas is connected at one end to the space between the side of the recess 90a and the top end of the rotation sleeve 92, and connected at the other end to the upper part of the vacuum container 1.

In the composition of FIG. 18, the opening for supplying the second separation gas to the space between the side of the recess 90a and the top end of the rotation sleeve 92 is disposed on both right and left sides. In order to prevent the BTBAS gas and the O₃ gas from being mixed in the area in the vicinity of the rotation sleeve 92, it is preferred to design the number of openings of the second separation gas supplying portion 51 to be the optimum.

In the embodiment of FIG. 18, the space between the side of the recess 90a and the top end of the rotation sleeve 92, when viewed from the side of the turntable 2, constitutes a separation gas discharge hole, and the separation gas discharge hole, the rotation sleeve 92 and the support 91 constitute the core area C located in the core of the vacuum container 1. Also in this embodiment, the temperature control pipes 81a-81e are arranged in the top plate, the side walls and the base part of the vacuum container 1, similar to the embodiment of FIG. 1.

The film deposition apparatus and method according to the invention is not restricted to using two reactive gases. Alternatively, three or more reactive gases on a substrate may be sequentially supplied. For example, in such a case, the first reactive gas supplying portion, the first separation gas supplying portion, the second reactive gas supplying portion, the second separation gas supplying portion, the third reactive gas supplying portion, and the third separation gas supplying portion are arranged on the periphery of the vacuum container 1 in this order in the rotational direction of the turntable, and the separation area including each separation gas supplying portion is arranged similar to the previously described embodiment.

In the previously described embodiment, the film deposition apparatus which performs MLD (molecular layer deposition) is illustrated. However, the invention is also applicable to a film deposition apparatus which performs CVD (chemical vapor deposition). In this case, a gas shower head may be arranged as a gas supplying unit on the top plate of the film deposition apparatus instead of the gas supplying portion, and the reactive gas may be supplied from the gas shower head to the wafer W.

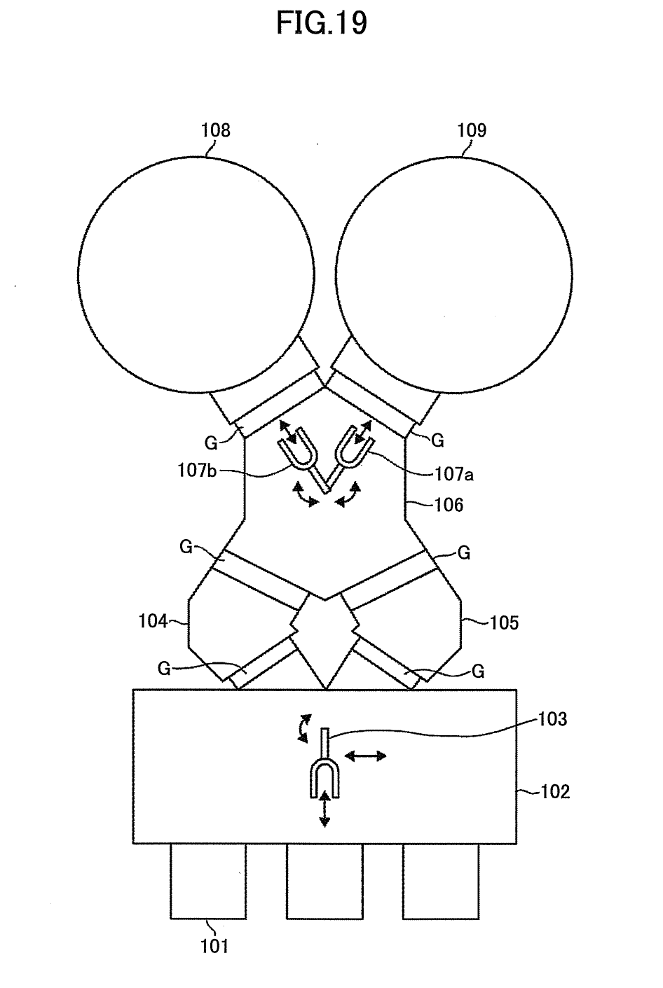

Next, FIG. 19 illustrates the composition of a substrate processing apparatus which uses the film deposition apparatus of at least one of the above-described embodiments of the invention.

As illustrated in FIG. 19, the substrate processing apparatus of this embodiment includes a conveyance container 101, an atmosphere conveyance container 102, a conveyance aim 103, load lock chambers 104 and 105, a vacuum conveyance container 106, a conveyance arm 107, and film deposition apparatuses 108 and 109.

The conveyance container 101 is a hermetically sealed conveyance container (called FOUP) which holds 25 wafers, for example. The atmosphere conveyance container 102 is an air conveyance chamber in which the conveyance arm 103 is arranged. Each of the load lock chambers 104 and 105 is arranged to switch the internal atmosphere of the chamber between air atmosphere and vacuum atmosphere. The vacuum conveyance container 106 is a vacuum conveyance chamber in which the two conveyance arms 107 are arranged. Each of the film deposition apparatuses 108 and 109 is constituted by the film deposition apparatus of at least one embodiment of the invention.

The conveyance container 101 is conveyed from the outside to the conveyance port provided with the mounting base (which is not illustrated), and installed therein. After the conveyance container 101 is installed, the lid of the air conveyance container 102 is opened by the opening/closing mechanism (which is not illustrated), and a wafer is taken out from the inside of the conveyance container 101 by the conveyance arm 103. The wafer taken out from the inside of the conveyance container 101 is carried in the load lock container 104 or 105.

Subsequently, the internal atmosphere of the load lock container 104 or 105 is switched to vacuum atmosphere from air atmosphere. Then, the wafer is taken out from the load lock container 104 or 105 by the conveyance arm 107, and conveyed to the film deposition apparatus 108 or 109. Then, in the film deposition apparatus 108 or 109, the film deposition processing is performed in accordance with the above-described film deposition method.

By using two or more film deposition apparatuses of at least one embodiment of the invention for five-sheet processing (for example, the two film deposition apparatuses 108, 109), it is possible for this embodiment to carry out the film deposition processing of ALD (or MLD) with high throughput.

As described in the foregoing, the film deposition apparatus and method of at least one embodiment of the invention can prevent the temperature of the vacuum container from being affected by the heating temperature of the substrate by using the substrate heating unit. It is possible to prevent the temperature of the vacuum container from becoming too high. Consequently, it is possible for the film deposition apparatus and method to prevent the film deposition processing from being affected.

The present invention is not limited to the above-described embodiments, and variations and modifications may be made without departing from the scope of the present invention.

What is claimed is:

1. A film deposition apparatus which deposits a multiple-layered thin film on a surface of a substrate by sequentially supplying two or more mutually reactive gases to the substrate in a vacuum container and repeating a gas supplying cycle, the film deposition apparatus comprising:
a turntable disposed in the vacuum container and including a substrate placement area in which a substrate is placed;
a substrate heating unit disposed to heat the substrate placed on the turntable;
first and second reactive gas supplying units disposed over the turntable at mutually distant locations in a rotational direction of the turntable to respectively supply first and second reactive gases to first and second processing areas adjacent to the substrate placement area of the turntable;
a separation gas supplying unit disposed over the turntable to supply a separation gas to a separation area located between the first and second processing areas in the rotational direction of the turntable, so that the first reactive gas in the first processing area and the second reactive gas in the second processing area are separated from each other by the separation gas;
an exhaust port arranged to exhaust the first and second reactive gases and the separation gas from the turntable; and
a temperature control part arranged to heat or cool the vacuum container.

2. The film deposition apparatus according to claim 1, wherein the temperature control part comprises a temperature control fluid passage disposed in the vacuum container.

3. The film deposition apparatus according to claim 1, wherein the temperature control part comprises a cooling fluid passage disposed in the vacuum container, and a heating unit disposed in the vacuum container.

4. The film deposition apparatus according to claim 1, wherein the temperature control part is disposed in at least one of a bottom part and a ceiling part of the vacuum container.

5. The film deposition apparatus according to claim 4, wherein the temperature control part is disposed on a side wall of the vacuum container.

6. The film deposition apparatus according to claim 1, wherein the first reactive gas is a reactive gas into which a solid material or a liquid material is vaporized.

7. The film deposition apparatus according to claim 1, wherein the temperature control part is arranged to heat the vacuum container according to a predetermined temperature of the substrate in order to maintain the first reactive gas, obtained by vaporizing a solid material or a liquid material, in a gaseous state.

8. The film deposition apparatus according to claim 1, wherein the substrate heating unit is disposed on a lower part side of the turntable.

9. The film deposition apparatus according to claim 1, wherein the separation area is located on each of right and left sides of the separation gas supplying unit in the rotational direction of the turntable, and includes an undersurface portion to form a narrow space between the separation area and the turntable for enabling the separation gas to flow from the separation area to the first and second processing areas.

10. The film deposition apparatus according to claim 1, further comprising a central area located in a central part of the vacuum container, wherein an ejection hole is formed in the central area for discharging the separation gas to the substrate mounting surface of the turntable to separate the first reactive gas in the first processing area and the second reactive gas in the second processing area,
wherein the first and second reactive gases are exhausted from the exhaust port together with the separation gas discharged from both sides of the separation area and the separation gas discharged from the central area.

11. A film deposition method which deposits a multiple-layered thin film on a surface of a substrate by sequentially supplying two or more mutually reactive gases to the substrate in a vacuum container of a film deposition apparatus and repeating a gas supplying cycle, the film deposition method comprising:
placing a substrate in a substrate placement area of a turntable disposed in the vacuum container, and rotating the turntable;
supplying first and second reactive gases to first and second processing areas adjacent to the substrate placement area of the turntable, respectively, by first and second reactive gas supplying units disposed over the turntable at mutually distant locations in a rotational direction of the turntable;
supplying a separation gas to a separation area located between the first and second processing areas in the rotational direction of the turntable, by a separation gas supplying unit disposed over the turntable, so that the first reactive gas in the first processing area and the second reactive gas in the second processing area are separated from each other by the separation gas;
exhausting the first and second reactive gases and the separation gas from the turntable through an exhaust port;
heating the substrate placed on the turntable by a substrate heating unit of the film deposition apparatus; and
heating or cooling the vacuum container by a temperature control part of the film deposition apparatus.

12. The film deposition method according to claim 11, wherein the heating or cooling the vacuum container by the temperature control part includes flowing a temperature control fluid through a temperature control fluid passage disposed in the vacuum container.

13. The film deposition method according to claim 11, wherein the heating or cooling the vacuum container by the temperature control part includes:
flowing a cooling fluid through a cooling fluid passage disposed in the vacuum container; and heating the vacuum container by a heating unit of the temperature control part.

14. The film deposition method according to claim 11, wherein the separation area is located on each of right and left sides of the separation gas supplying unit in the rotational direction of the turntable, and includes an undersurface portion to form a narrow space between the separation area and the turntable for enabling the separation gas to flow from the separation area to the first and second processing areas.

15. The film deposition method according to claim 11, further comprising discharging the separation gas from an ejection hole to the substrate mounting surface of the turntable to separate the first reactive gas in the first processing area and the second reactive gas in the second processing area,
wherein the ejection hole is formed in a central area located in a central part of the vacuum container,
wherein the first and second reactive gases are exhausted from the exhaust port together with the separation gas discharged from both sides of the separation area and the separation gas discharged from the central area.

16. A computer-readable storage medium storing a program which, when executed by a computer, causes the computer to perform the film deposition method according to claim 11.
